(19) United States
(12) Patent Application Publication
(10) Pub. No.: US 2019/0071762 A1
(43) Pub. Date: Mar. 7, 2019

(54) SCAN VAPOR DEPOSITION METAL MASK, VAPOR DEPOSITION DEVICE, VAPOR DEPOSITION METHOD, AND ELECTROLUMINESCENCE DISPLAY DEVICE

(71) Applicant: Sharp Kabushiki Kaisha, Sakai City, Osaka (JP)

(72) Inventors: Yuhki KOBAYASHI, Sakai City (JP); Katsuhiro KIKUCHI, Sakai City (JP); Shinichi KAWATO, Sakai City (JP); Satoshi INOUE, Sakai City (JP); Manabu NIBOSHI, Sakai City (JP)

(21) Appl. No.: 15/765,494

(22) PCT Filed: Oct. 14, 2016
(86) PCT No.: PCT/JP2016/080589

§ 371 Date: Apr. 3, 2018

(30) Foreign Application Priority Data
Oct. 21, 2015 (JP) 2015-207306

(51) Int. Cl. C23C 14/04; C23C 14/24; C23C 16/04; H01L 51/00; B32B 15/00

(52) U.S. Cl. CPC C23C 14/042; C23C 14/24; B32B 15/00; H01L 51/0008; C23C 16/042

(57) ABSTRACT

Provided is a scan vapor deposition metal mask with which a high-resolution, linear vapor deposition film pattern can be formed even on a large-sized substrate. Two first unit opening groups are included. The first unit opening groups are arranged by being shifted from each other in a Y direction so as not to be adjacent to each other in an X direction, while the first unit opening groups adjacent to each other in the Y direction are arranged by being shifted from each other in the X direction by ½ times a first opening pitch.

### TECHNICAL FIELD

The disclosure relates to a scan vapor deposition metal mask, a vapor deposition device provided with the scan vapor deposition metal mask, a vapor deposition method using the scan vapor deposition metal mask, and an electroluminescence display device produced using the vapor deposition method.

### BACKGROUND ART

A variety of flat panel displays have been developed in recent years, and organic electroluminescence (EL) display devices in particular have attracted significant attention as excellent flat panel displays due to the possibility of realizing lower power consumption, reduced thickness, higher picture quality, and the like.

In the field of such organic EL display devices, similarly to the field of liquid-crystal display devices, an increase in pixels per inch (ppi) of a display device is desired to realize even higher picture quality. In order to realize an increase in pixels per inch of a display device in the field of organic EL display devices, it is required that a higher-resolution vapor deposition film including a light-emitting layer can be formed on a substrate.

In a case where a vapor deposition method by color using a known metal mask is employed, however, it is difficult to form on a substrate a high-resolution vapor deposition film that supports 300 ppi or higher, due to limitations in opening positioning accuracy and opening pattern accuracy of a metal mask itself, i.e., limitations in processing accuracy of the metal mask.

Against this background, in order to improve processing accuracy of metal masks, developments have been under way in recent years to realize high-resolution vapor deposition by color that supports 300 ppi or higher by using a mask in which a metal layer and a resin layer are layered. PTL 1 discloses a large-sized mask in which a resin layer to be provided with an opening pattern is formed on a metal part with a plurality of slit patterns serving as a reinforcing member, and which corresponds to the entire substrate.

It is stated that according to the aforementioned configuration, the opening pattern is to be provided in the resin layer, not the metal layer, and thus processing accuracy of the mask can be improved.

Moreover, an attempt is made to realize high-resolution vapor deposition by color by performing vapor deposition by color while highly accurately moving, relative to a substrate, a large-sized vapor deposition mask corresponding to the entire substrate. PTL 2 states that by moving a vapor deposition mask relative to a substrate by using a fine motion mechanism using a pulse motor, precise positioning of the substrate and a pattern of the vapor deposition mask is facilitated, and since fine motion of the vapor deposition mask is performed on the basis of control according to the number of pulses of the pulse motor, light emitting portions with pitches as fine as pitches of several tens of microns can be formed. Furthermore, it is stated that by applying these methods to a process of producing an organic EL display device, pitches of light emitting portions can be narrowed to about one-third of pitches of light emitting portions of color organic EL display devices known in the related art, which makes it possible to produce a color organic EL display device including high-resolution light emitting portions with a pixel pitch (also referred to as trio pitch) of 100 microns or less and a subpixel pitch of several tens of microns. PTL 3 also describes, as in PTL 2, performing vapor deposition by color while moving, relative to a substrate, a large-sized film formation mask corresponding to the entire substrate.

### CITATION LIST

### Patent Literature

PTL 1: JP 2013-216978 A (published on Oct. 24, 2013).

PTL 2: JP 2000-188179 A (published on Jul. 4, 2000).

PTL 3: JP 08-227276 A (published on Sep. 3, 1996).

### SUMMARY

### Technical Problem

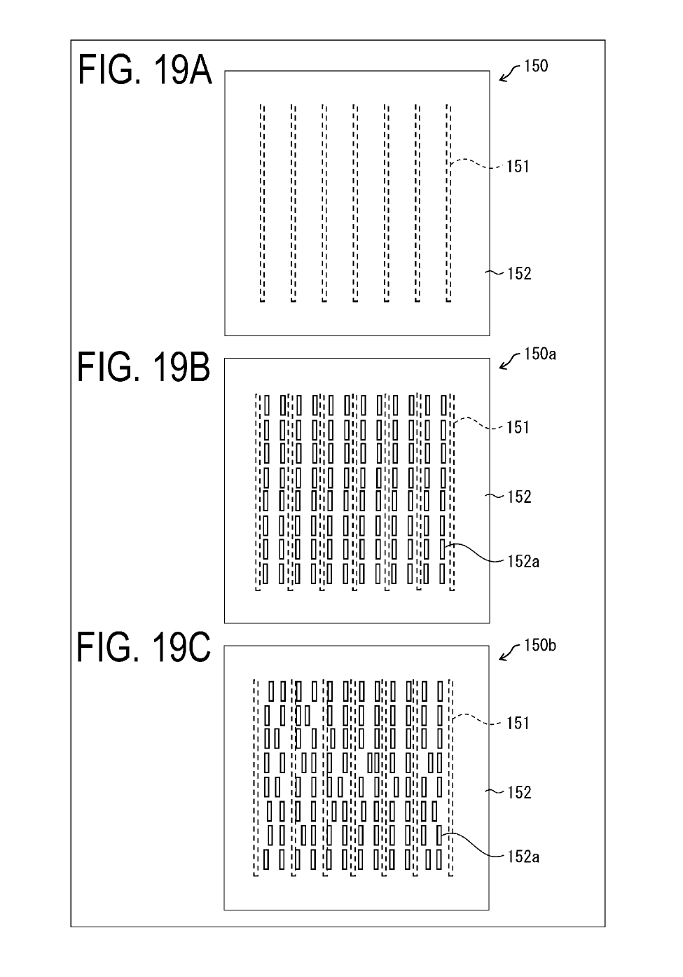

FIG. 19A to FIG. 19C illustrate diagrams for describing a problem of the known large-sized mask disclosed in PTL 1.

As illustrated in FIG. 19A, a known large-sized mask 150 corresponding to the entire substrate has a configuration in which a resin layer 152 to be provided with an opening pattern is formed on a metal part 151 with a plurality of slit patterns that serves as a reinforcing member. Formation of a vapor deposition film with a prescribed pattern is performed through openings formed in the resin layer 152 while the metal part 151 with the plurality of slit patterns function as a base of the mask 150.

Openings 152a are optically formed in the resin layer 152 by using a laser, and thus expectedly, a mask 150a that satisfies high opening positioning accuracy and high opening pattern accuracy can be realized as illustrated in FIG. 19B.

However, in a case where the mask is a large-sized mask corresponding to the entire substrate, provision of the metal part 151 with the plurality of slit patterns that serves as a reinforcing member is not very effective in actuality, such that mask tension collapses when the openings 152a are optically formed in the resin layer 152 by using a laser, resulting in a mask 150b with poor opening positioning accuracy and opening pattern accuracy as illustrated in FIG. 19C.

As described above, in the case of a mask in which the resin layer 152 is formed on the metal part 151 with the plurality of slit patterns that serves as a reinforcing member and the openings 152a are optically formed in the resin layer 152 by using a laser, a mask size that can be produced is limited, when it is taken into account that mask tension collapses when the openings 152a are optically formed in the resin layer 152 by using a laser, and therefore, there is a problem that it is difficult to apply the technique not only to a large-sized mask corresponding to the entire substrate, but also to a scan vapor deposition mask that is smaller in size than a substrate (a mask that is designed for performing vapor deposition by moving either one of a substrate and the mask relative to the other).

PTL 2 only discloses a known large-sized mask corresponding to the entire substrate. Unlike a scan vapor deposition mask, a large-sized mask corresponding to the entire substrate needs to be a mask that has an equivalent size to the size of the substrate, and hence there is a fundamental problem that the mask cannot be used for a large-sized substrate with a certain size or greater.

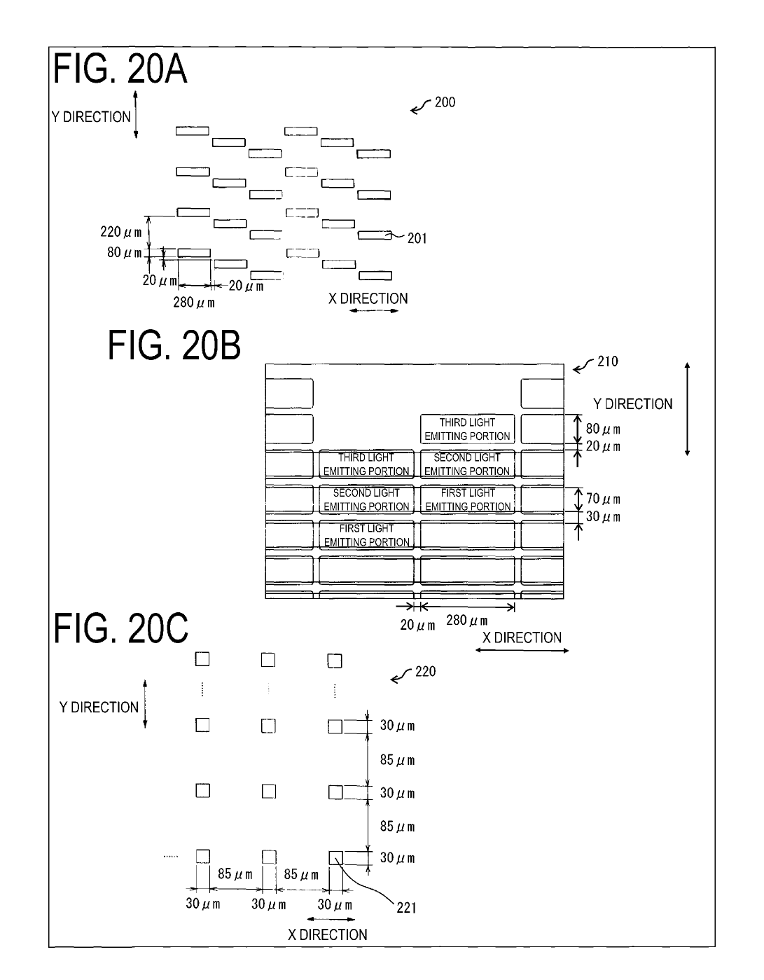

FIG. 20A to FIG. 20C illustrate diagrams for describing a problem of the known large-sized mask disclosed in PTL 2.

In a large-sized mask 200 illustrated in FIG. 20A, openings 201 are arranged in a staggered manner, and pitches for a pattern of the openings 201 in an X direction and a Y direction are set to be relatively large. However, since the large-sized mask 200 is a large-sized mask corresponding to the entire substrate, when vapor deposition by color of first light emitting portions, second light emitting portions, and third light emitting portions is performed while moving the large-sized mask 200 step-wise in the X direction and the Y direction, the first light emitting portions are formed in a staggered pattern and also the second light emitting portions and the third light emitting portions are formed in staggered patterns, on a substrate 210 as illustrated in FIG. 20B, and therefore, the first light emitting portions are not formed in a stripe pattern that is a pattern where the first light emitting portions are arranged linearly in the X direction or the Y direction. The same is applied to the second light emitting portions and the third light emitting portions. PTL 2 also discloses a case in which openings are arranged in a pattern that is other than a staggered pattern. As illustrated in FIG. 20C, in a large-sized mask 220, openings 221 are formed at 85 μm intervals in the X direction and the Y direction. However, since the large-sized mask 220 is a large-sized mask corresponding to the entire substrate, when vapor deposition by color for vapor deposition films of a plurality of types is performed while moving the large-sized mask 220 step-wise in the X direction and the Y direction, then the vapor deposition films of the plurality of types are not formed in a stripe pattern.

As described above, in a case where a vapor deposition film formed in a prescribed pattern on a substrate corresponding to subpixels of an organic EL display device is formed in a pattern other than a stripe pattern, such as a staggered pattern, for example, a subpixel is shared by a plurality of pixels, and therefore, there is a problem that jaggies, i.e., straight lines or contours of characters becoming stairlike, occur, and favorable display cannot be obtained.

Moreover, in PTL 2, when performing the vapor deposition by color, the large-sized masks 200 and 220 need to be moved step-wise in the X direction and the Y direction, and hence positioning with high precision is required. Therefore, in a case where it is difficult to obtain positioning with high precision, margins need to be secured at openings, leading to a need for reduction in size of the openings.

PTL 3 also discloses only a known large-sized mask corresponding to the entire substrate.

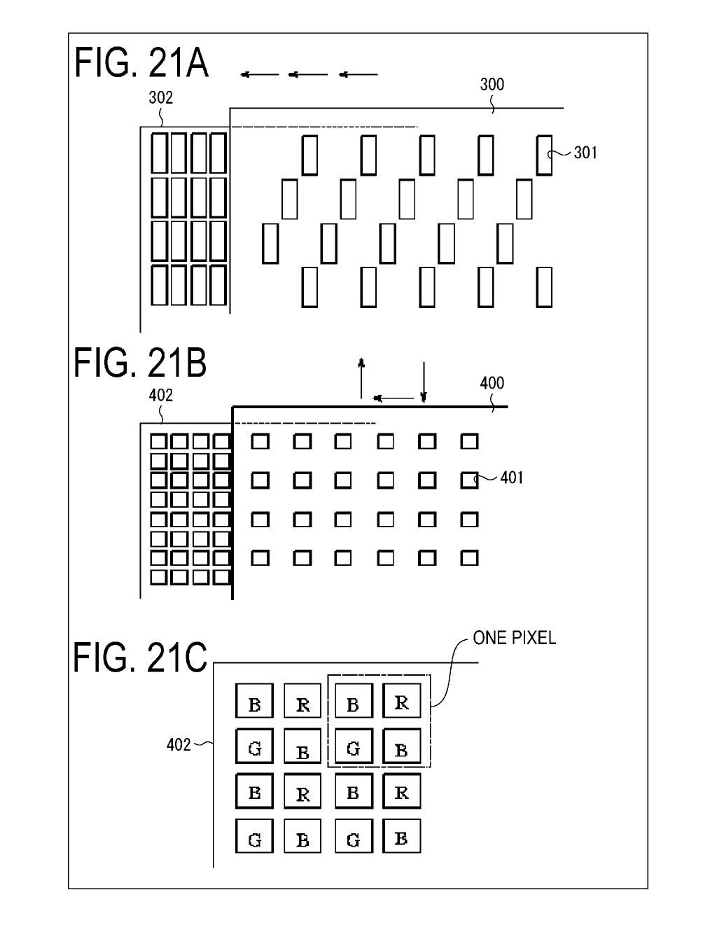

FIG. 21A to FIG. 21C illustrate diagrams for describing a problem of the known large-sized mask disclosed in PTL 3.

In a large-sized mask 300 illustrated in FIG. 21A, openings 301 are arranged in a staggered manner. Since the large-sized mask 300 is a large-sized mask corresponding to the entire substrate, when vapor deposition by color for a vapor deposition film is performed while moving the large-sized mask 300 step-wise, the vapor deposition film is formed on the substrate in a staggered pattern instead of being formed in a stripe pattern. PTL 3 also discloses a case in which openings are arranged in a pattern other than a staggered pattern. As illustrated in FIG. 21B, in a large-sized mask 400, openings 401 are formed at prescribed intervals in an X direction and a Y direction. However, since the large-sized mask 400 is a large-sized mask corresponding to the entire substrate, when vapor deposition by color for R color light-emitting films, G color light-emitting films, and B color light-emitting films is performed on a substrate 402 while moving the large-sized mask 400 step-wise in the X direction and the Y direction, none of the R color light-emitting films, G color light-emitting films, and B color light-emitting films are formed in a stripe pattern as illustrated in FIG. 21C.

As described above, the known large-sized mask disclosed in PTL 3 has a similar problem to the problem of the known large-sized mask disclosed in PTL 2 mentioned above.

The disclosure has been devised in view of the problems described above, and an object thereof is to provide a scan vapor deposition metal mask, a vapor deposition device, and a vapor deposition method according to which a high-resolution, linear vapor deposition film pattern can be formed even on a large-sized substrate.

### Solution to Problem

To solve the above-described problems, a scan vapor deposition metal mask according to the disclosure includes a plurality of openings formed into an identical width in a first direction. Each of first unit opening groups is constituted by part of the plurality of openings, each two of the part of the plurality of openings adjacent to each other in the first direction being arranged at a first interval from each other, and one or more of the part of the plurality of openings being arrayed in a second direction orthogonal to the first direction. The plurality of openings belong to one or more second unit opening groups each constituted by N (N is an integer of two or more) of the first unit opening groups. The N first unit opening groups are arranged by being shifted from each other in the second direction, the first unit opening groups not being adjacent to each other in the first direction, while each two of the first unit opening groups adjacent to each other in the second direction are arranged by being shifted from each other in the first direction by 1/N times the first interval. In each of the first unit opening groups, one or more openings of the plurality openings arrayed in the second direction serve as openings for forming a linear vapor deposition film pattern having an identical width in the first direction and aligned with the second direction.

Scan vapor deposition is a vapor deposition method of, by using a scan vapor deposition mask smaller than a substrate on which a vapor deposition film pattern is to be formed, vapor-depositing a vapor deposition film pattern on the substrate while scanning (moving) either one of the substrate and the scan vapor deposition mask with respect to the other. The scan vapor deposition metal mask is a metal mask that is used in such scan vapor deposition.

According to the above configuration, the scan vapor deposition metal mask is a metal mask, which can prevent poor opening positioning accuracy and opening pattern accuracy due to collapse of mask tension as in a case of a mask using a resin layer. In addition, even in a case of a large-sized substrate, using the scan vapor deposition metal mask enables formation of a vapor deposition film pattern without increasing the mask size.

In a case of using a metal mask, it is difficult to decrease the interval between openings to a prescribed value or lower due to limitations in opening positioning accuracy and opening pattern accuracy of the metal mask itself, i.e., limitations in processing accuracy of the metal mask, and is hence difficult to provide a metal mask with which a high-resolution vapor deposition film pattern can be formed.

According to the above configuration, in each of the first unit opening groups, the one or more openings arrayed in the second direction are one or more openings for forming a linear vapor deposition film pattern having an identical width in the first direction and aligned with the second direction, the N first unit opening groups (N is an integer of two or more) are included, and the N first unit opening groups are arranged by being shifted from each other in the second direction such that the first unit opening groups are not to be adjacent from each other in the first direction, while the first unit opening groups adjacent to each other in the second direction are arranged by being shifted from each other in the first direction by 1/N times the first interval.

Hence, in a case of attempting to form, on a substrate, vapor deposition film patterns with the same density by using the scan vapor deposition metal mask, in which the arrangement of the openings is improved as described above, and a known metal mask in which openings are not arranged by being shifted in the first direction and the second direction, it is possible, with the scan vapor deposition metal mask, to increase the first interval, i.e., the interval between adjacent openings in the first direction, to N times the interval between openings in the known metal mask, and hence to fulfill high opening positioning accuracy and high opening pattern accuracy although the scan vapor deposition metal mask is a metal mask.

Hence, with the above configuration, it is possible to provide a scan vapor deposition metal mask with which a high-resolution, linear vapor deposition film pattern can be formed even on a large-sized substrate.

A vapor deposition method according to the disclosure is, to solve the above-described problems, a vapor deposition method for forming vapor deposition film patterns on a substrate by using a vapor deposition particle emission portion including an emission port configured to emit vapor deposition particles and a scan vapor deposition metal mask including a plurality of openings having an identical width in a first direction, a first unit opening group in the scan vapor deposition metal mask being constituted by part of the plurality of openings, each two of the part of the plurality of openings adjacent to each other in the first direction being arranged at a first interval from each other, one or more of the part of the plurality of openings being arrayed in a second direction orthogonal to the first direction, the plurality of openings belonging to one second unit opening group constituted by N (N is an integer of two or more) of the first unit opening groups, the N first unit opening groups being arranged by being shifted from each other in the second direction, the first unit opening groups not being adjacent to each other in the first direction, while each two of the first unit opening groups adjacent to each other in the second direction being arranged by being shifted from each other in the first direction by 1/N times the first interval, and in each of the first unit opening groups, one or more openings of the plurality of openings arrayed in the second direction serving as openings for forming a linear vapor deposition film pattern having an identical width in the first direction and aligned with the second direction. The vapor deposition method includes: forming a first vapor deposition film pattern having a linear shape, aligned with the second direction, and having an identical width in the first direction, while moving either one of the substrate and a vapor deposition unit including the scan vapor deposition metal mask and the vapor deposition particle emission portion, with respect to another in the second direction; after forming the first vapor deposition film pattern, forming a second vapor deposition film pattern having a linear shape, aligned with the second direction, and having an identical width in the first direction, while moving the one of the substrate and the vapor deposition unit in the second direction, after moving the one in the first direction, with respect to the other; and after forming the second vapor deposition film pattern, forming a third vapor deposition film pattern having a linear shape, aligned with the second direction, and having an identical width in the first direction, while moving the one of the substrate and the vapor deposition unit in the second direction, after moving the one in the first direction, with respect to the other.

With the above method, it is possible to provide a vapor deposition method in which a high-resolution, linear vapor deposition film pattern can be formed even on a large-sized substrate, by using a relatively small-sized scan vapor deposition metal mask.

A vapor deposition method according to the disclosure is, to solve the above-described problems, a vapor deposition method for forming vapor deposition film patterns on a substrate by using a vapor deposition particle emission portion including a plurality of emission ports configured to emit vapor deposition particles, a scan vapor deposition metal mask including a plurality of openings having an identical width in a first direction, and a restriction plate unit included between the scan vapor deposition metal mask and the vapor deposition particle emission portion and including a plurality of through holes for restricting an incident angle of vapor deposition particles to the scan vapor deposition metal mask within a certain range, the vapor deposition particles being emitted from a corresponding one of the plurality of emission ports, a first unit opening group in the scan vapor deposition metal mask being constituted by part of the plurality of openings, each two of the part of the plurality of openings adjacent to each other in the first direction being arranged at a first interval from each other, one or more of the part of the plurality of openings being arrayed in a second direction orthogonal to the first direction, the plurality of openings belonging to two or more second unit opening groups each constituted by N (N is an integer of two or more) of the first unit opening groups, the N first unit opening groups being arranged by being shifted from each other in the second direction, the first unit opening groups not being adjacent to each other in the first direction, while each two of the first unit opening groups adjacent to each other in the second direction being arranged by being shifted from each other in the first direction by 1/N times the first interval, and in each of the first unit opening groups, one or more openings of the plurality of openings arrayed in the second direction serving as openings for forming a linear vapor deposition film pattern having an identical width in the first direction and aligned with the second direction. The vapor deposition method includes: forming a first vapor deposition film pattern having a linear shape, aligned with the second direction, and having an identical width in the first direction, while moving either one of a vapor deposition unit including the restriction plate unit, the scan vapor deposition metal mask, and the vapor deposition particle emission portion, and the substrate, with respect to another in the second direction; after forming the first vapor deposition film pattern, forming a second vapor deposition film pattern having a linear shape, aligned with the second direction, and having an identical width in the first direction, while moving the one of the vapor deposition unit and the substrate, after moving the one in the first direction, with respect to the other in the second direction; and after forming the second vapor deposition film pattern, forming a third vapor deposition film pattern having a linear shape, aligned with the second direction, and having an identical width in the first direction, while moving the one of the vapor deposition unit and the substrate, after moving the one in the first direction, with respect to the other in the second direction.

With the above method, it is possible to provide a vapor deposition method in which a high-resolution, linear vapor deposition film pattern can be highly efficiently formed even on a large-sized substrate.

### Advantageous Effects of Disclosure

According to an aspect of thedisclosure, it is possible to provide a scan vapor deposition metal mask, a vapor deposition device, and a vapor deposition method according to which a high-resolution, linear vapor deposition film pattern can be formed even on a large-sized substrate.

### BRIEF DESCRIPTION OF DIAGRAMS

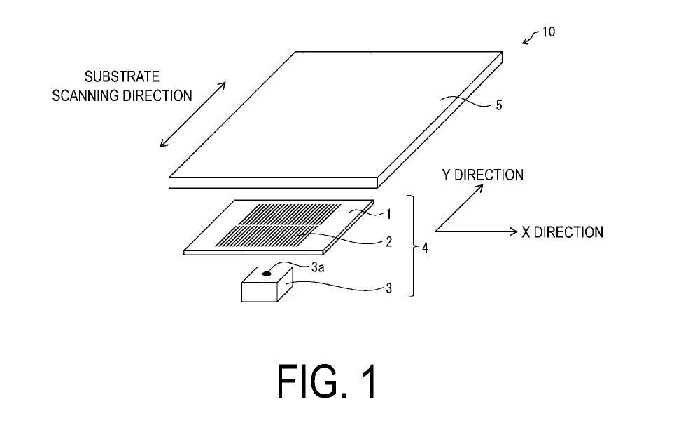

FIG. 1 is a diagram illustrating an overall configuration of a vapor deposition device according to Embodiment 1 of the disclosure, the diagram illustrating a case where a substrate is scanned.

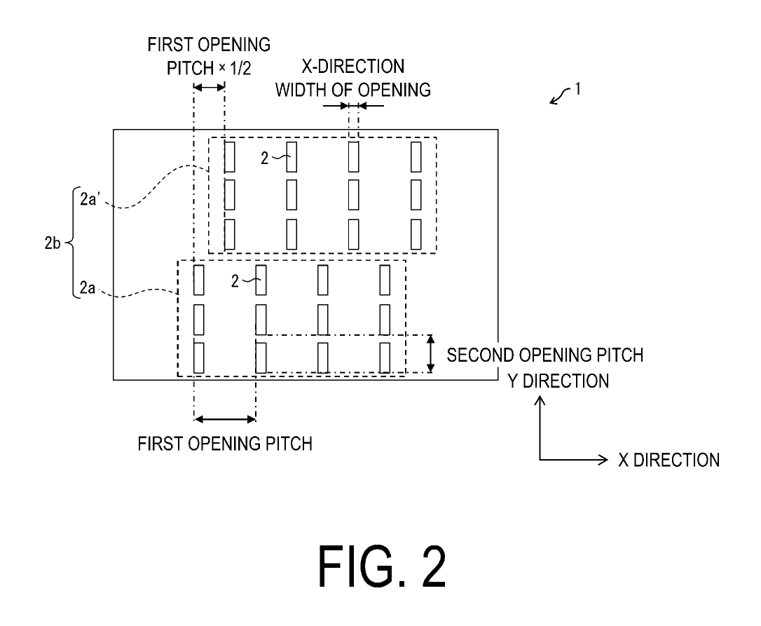

FIG. 2 is a diagram illustrating a scan vapor deposition metal mask provided to the vapor deposition device illustrated in FIG. 1.

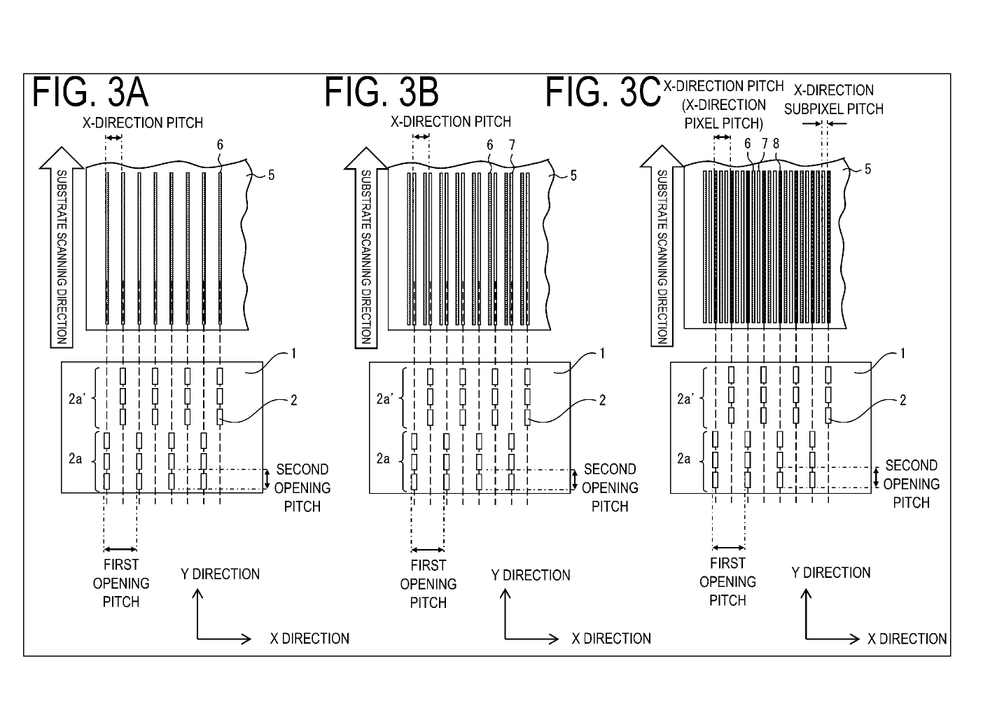

FIG. 3A to FIG. 3C are diagrams illustrating an example of a process for forming vapor deposition film patterns on a substrate by using the scan vapor deposition metal mask illustrated in FIG. 2.

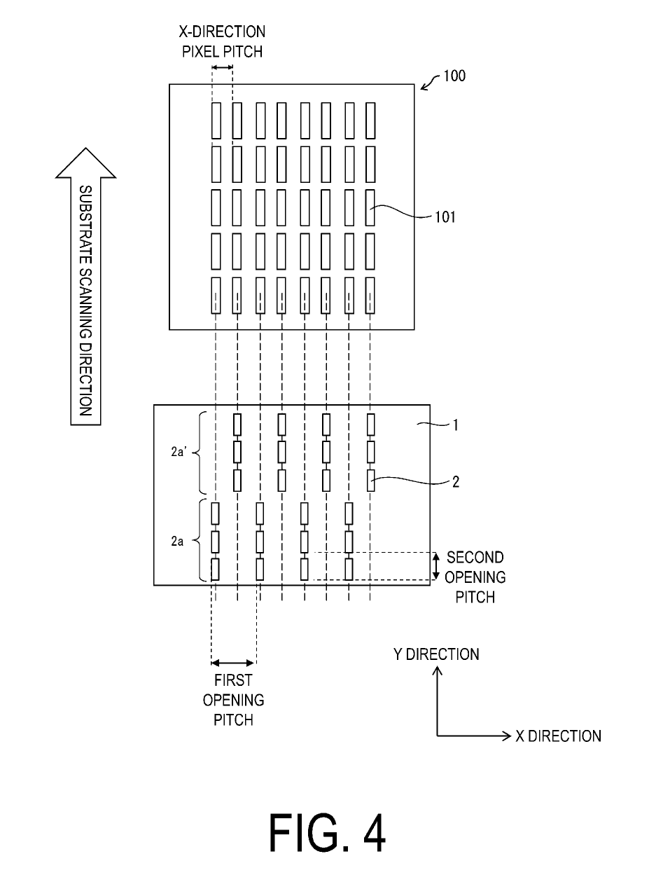

FIG. 4 is a diagram illustrating an interval between adjacent openings in an X direction in a known metal mask and an interval between adjacent openings in the X direction in the scan vapor deposition metal mask illustrated in FIG. 2.

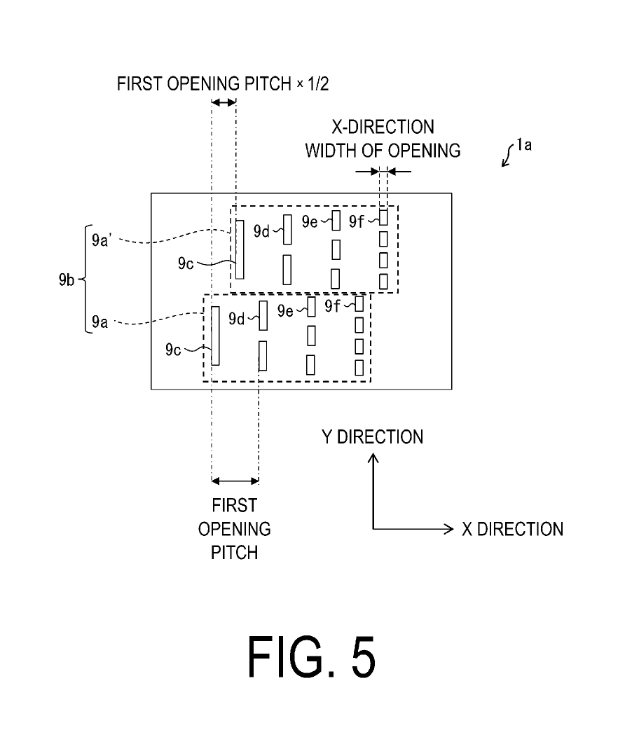

FIG. 5 is a diagram illustrating a modification of the scan vapor deposition metal mask that can be provided to the vapor deposition device illustrated in FIG. 1.

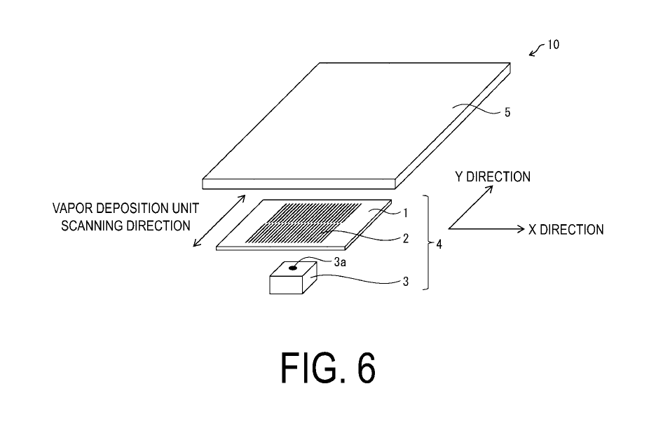

FIG. 6 is a diagram illustrating an overall configuration of the vapor deposition device according to Embodiment 1 of thedisclosure, the diagram illustrating a case where a vapor deposition unit is scanned.

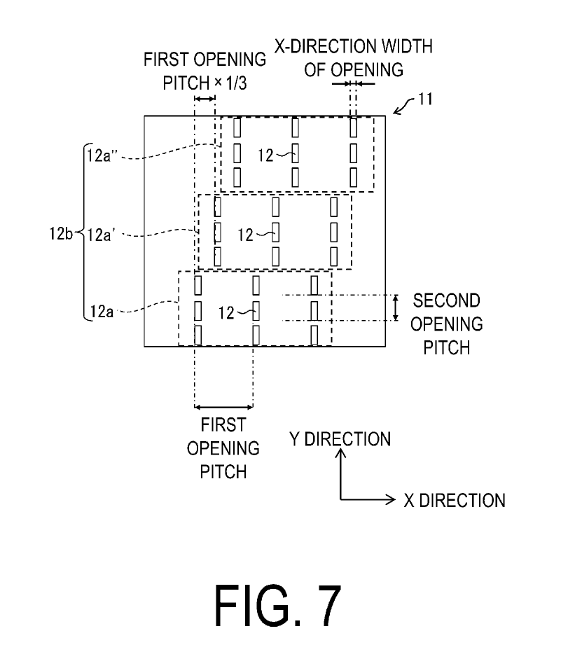

FIG. 7 is a diagram illustrating a scan vapor deposition metal mask according to Embodiment 2 of the disclosure that can be provided on the vapor deposition device illustrated in FIG. 1.

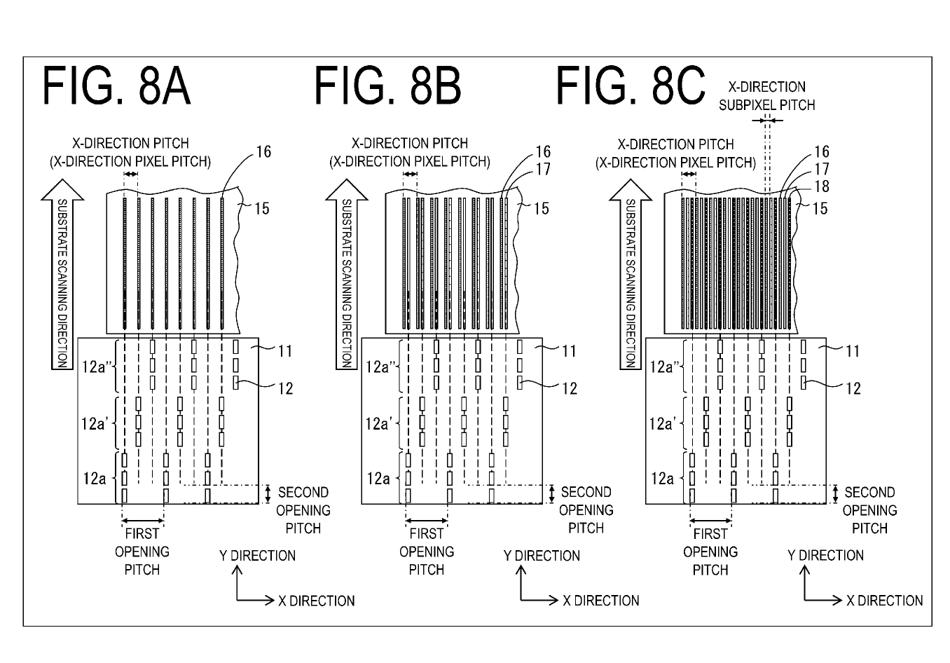

FIGS. 8A to 8C are diagrams illustrating an example of a process for forming vapor deposition film patterns on a substrate by using the scan vapor deposition metal mask illustrated in FIG. 7.

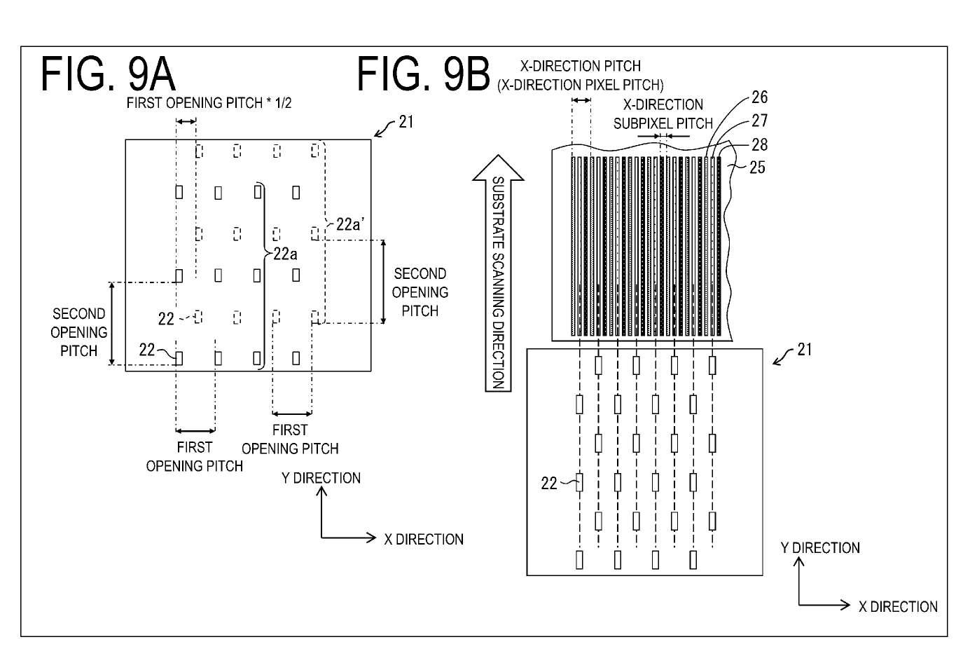

FIG. 9A is a diagram illustrating a scan vapor deposition metal mask according to Embodiment 3 of the disclosure that can be provided to the vapor deposition device illustrated in FIG. 1, and FIG. 9B is a diagram illustrating an example of a process for forming vapor deposition film patterns on a substrate by using the scan vapor deposition metal mask according to Embodiment 3 of thedisclosure.

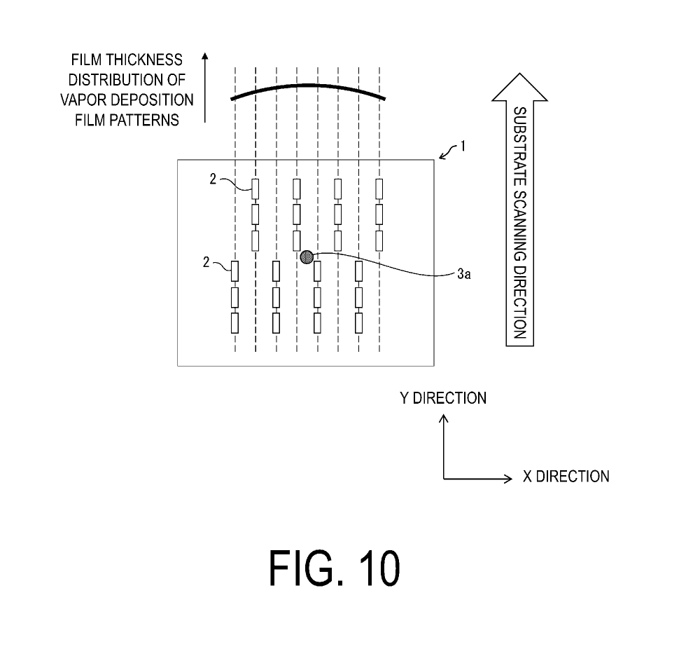

FIG. 10 is a diagram for describing a film thickness distribution that can occur according to a distance from an emission port of a vapor deposition particle emission portion in a case where vapor deposition film patterns are formed on a substrate by using the scan vapor deposition metal mask illustrated in FIG. 2.

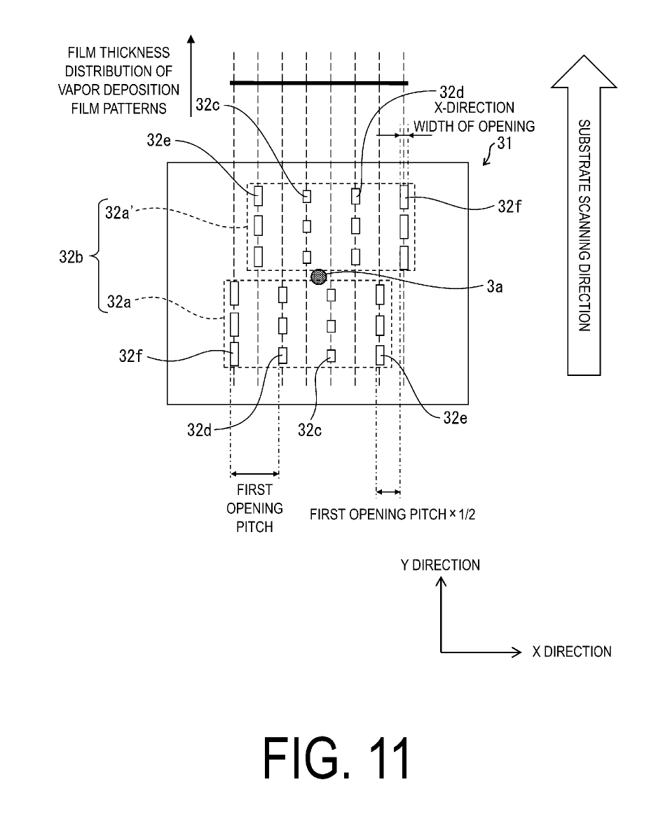

FIG. 11 is a diagram illustrating a scan vapor deposition metal mask according to Embodiment 4 of the disclosure and a film thickness distribution that can occur according to a distance from the emission port of the vapor deposition particle emission portion in a case where vapor deposition film patterns are formed on a substrate by using the scan vapor deposition metal mask.

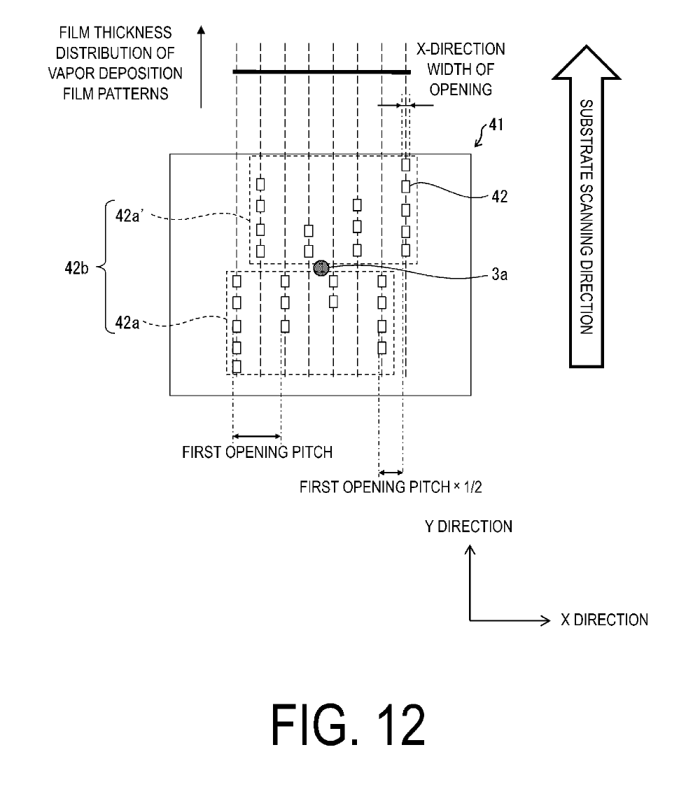

FIG. 12 is a diagram illustrating another scan vapor deposition metal mask according to Embodiment 4 of the disclosure and a film thickness distribution that can occur according to a distance from the emission port of the vapor deposition particle emission portion when vapor deposition film patterns are formed on a substrate by using the scan vapor deposition metal mask.

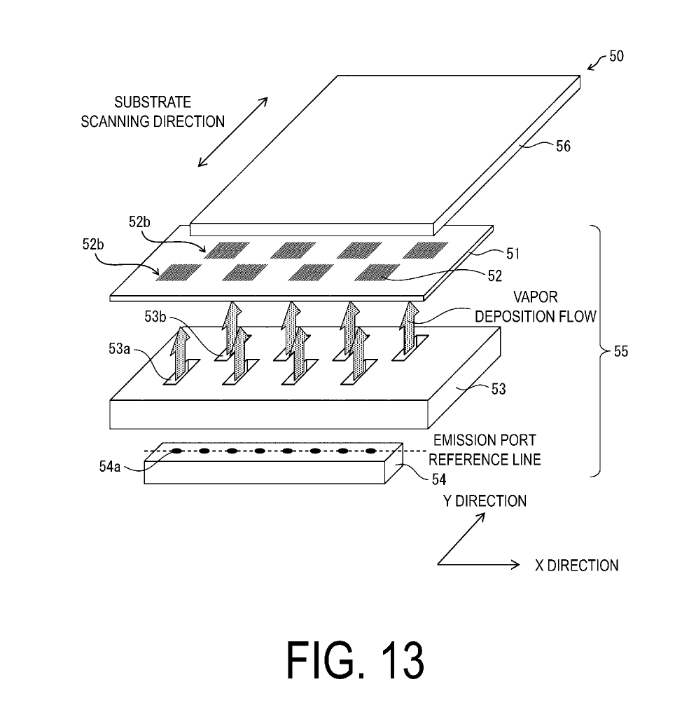

FIG. 13 is a diagram illustrating an overall configuration of a vapor deposition device according to Embodiment 5 of thedisclosure, the diagram illustrating a case where a substrate is scanned.

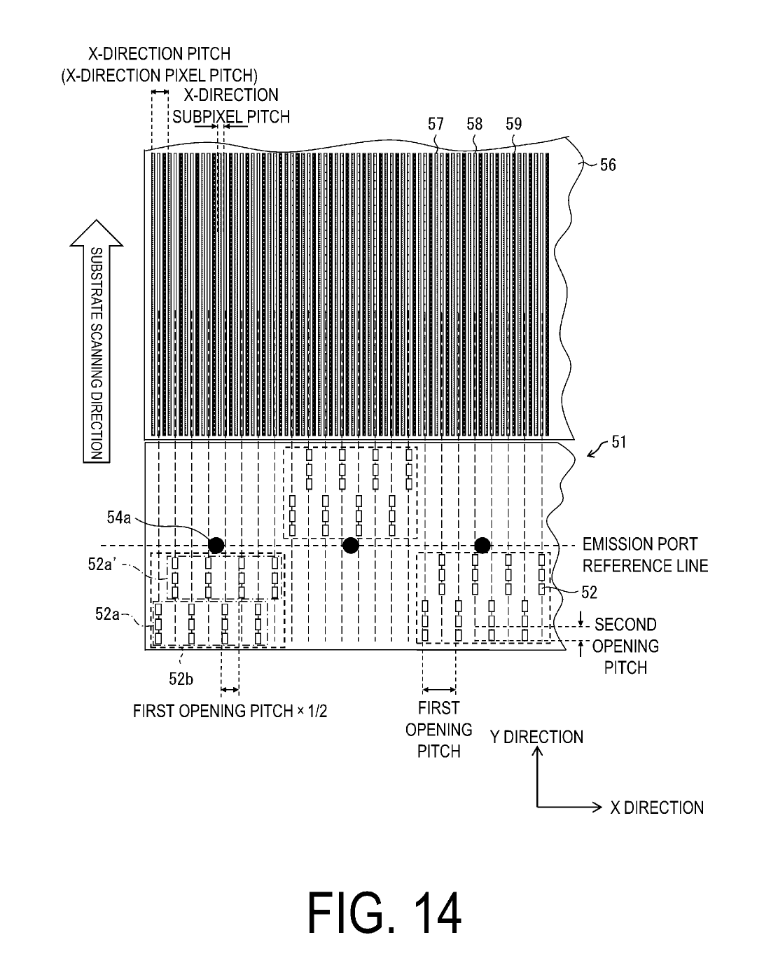

FIG. 14 is a diagram illustrating a scan vapor deposition metal mask provided to the vapor deposition device illustrated in FIG. 13 and an example of a process for forming vapor deposition film patterns on a substrate by using the scan vapor deposition metal mask.

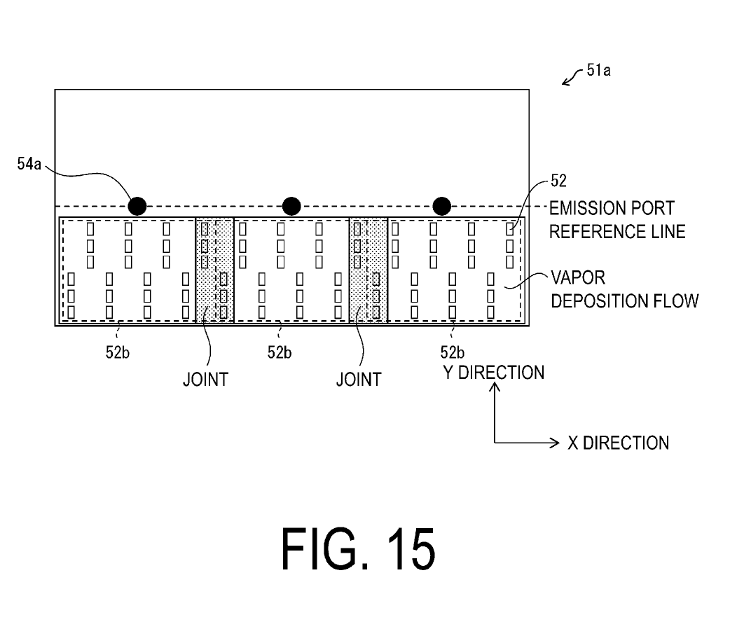

FIG. 15 is a diagram illustrating a comparative example of a scan vapor deposition metal mask.

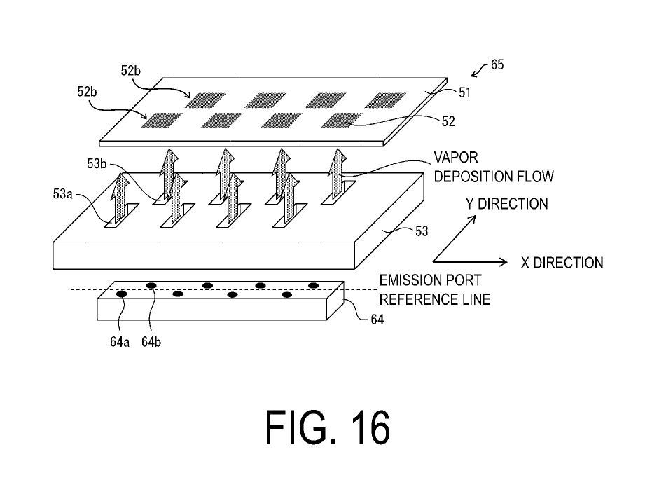

FIG. 16 is a diagram illustrating an overall configuration of a vapor deposition device according to Embodiment 6 of thedisclosure.

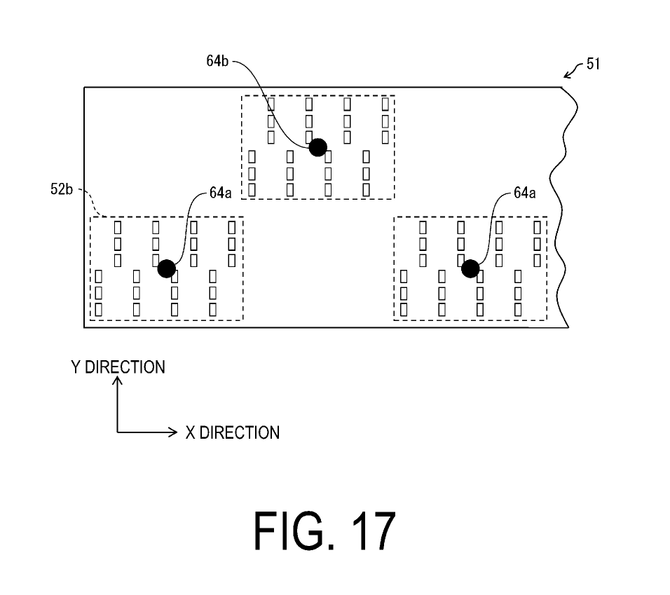

FIG. 17 is a diagram illustrating the position of each of a plurality of emission ports of a vapor deposition particle emission portion relative to the position of each of a plurality of second unit opening groups of a scan vapor deposition metal mask provided to the vapor deposition device illustrated in FIG. 16.

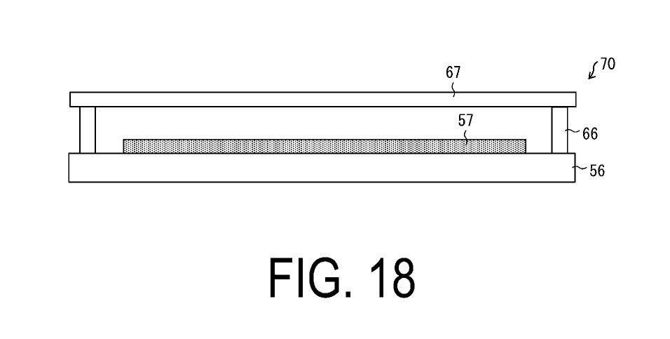

FIG. 18 is a diagram illustrating an overall configuration of an organic EL display device including the substrate on which the vapor deposition film patterns illustrated in FIG. 14 are formed.

FIG. 19A to FIG. 19C are diagrams for describing a problem of a known large-sized mask disclosed in PTL 1.

FIG. 20A to FIG. 20C are diagrams for describing a problem of a known large-sized mask disclosed in PTL 2.

FIG. 21A to FIG. 21C are diagrams for describing a problem of a known large-sized mask disclosed in PTL 3.

### DESCRIPTION OF EMBODIMENTS

A description follows regarding embodiments of thedisclosure, with reference to FIG. 1 to FIG. 18. In the following, for the sake of convenience in a description, there are cases where a configuration that has the same function as a configuration described in a certain embodiment is assigned the same reference sign, and a description thereof is omitted.

### Embodiment 1

With reference to FIG. 1 to FIG. 6, description will be given on a scan vapor deposition metal mask 1 and a vapor deposition device 10 provided with the scan vapor deposition metal mask 1 that are used when a vapor deposition film is formed on a substrate, for example, in a process of producing an organic electroluminescence (EL) display device.

FIG. 1 is a diagram illustrating an overall configuration of the vapor deposition device 10, the diagram illustrating a case where a substrate 5 is scanned (moved) with respect to a vapor deposition unit 4.

As illustrated in FIG. 1, the vapor deposition device 10 includes the vapor deposition unit 4 and the substrate 5.

The vapor deposition unit 4 includes the scan vapor deposition metal mask 1 in which openings 2 are formed, and a vapor deposition particle emission portion 3 provided with an emission port 3a configured to emit vapor deposition particles.

The vapor deposition particle emission portion 3 is arranged, with respect to the scan vapor deposition metal mask 1, at a position where vapor deposition particles emitted from the emission port 3a of the vapor deposition particle emission portion 3 can be supplied to a plurality of openings 2 of the scan vapor deposition metal mask 1, and the emission port 3a of the vapor deposition particle emission portion 3 is arranged so as to face the scan vapor deposition metal mask 1 and at a substantially central portion of a region where the plurality of openings 2 of the scan vapor deposition metal mask 1 are formed.

In the present embodiment, description is given by taking as an example a case where the emission port 3a of the vapor deposition particle emission portion 3 is arranged at a substantially central portion of the region where the plurality of openings 2 of the scan vapor deposition metal mask 1 are formed, however, as long as vapor deposition particles emitted from the emission port 3a of the vapor deposition particle emission portion 3 can be supplied to the plurality of openings 2 of the scan vapor deposition metal mask 1, the position of the emission port 3a of the vapor deposition particle emission portion 3 relative to the scan vapor deposition metal mask 1 is not limited to such an example.

The vapor deposition particle emission portion 3 (also referred to as a nozzle) generates gaseous vapor deposition particles by either heating a vapor deposition material to vaporize the same (in a case where the vapor deposition material is a liquid material) or through sublimation of the same (in a case where the vapor deposition material is a solid material) and emits the gaseous vapor deposition particles from the emission port 3a to the outside. In the vapor deposition particle emission portion 3, an upper surface where the emission port 3a is provided may be heated to or above the vaporization temperature or sublimation temperature of the vapor deposition material so as to prevent clogging of the vapor deposition material.

The vapor deposition material may be directly accommodated inside the vapor deposition particle emission portion 3 or may be supplied to the inside of the vapor deposition particle emission portion 3 from the outside of the vapor deposition particle emission portion 3 through a load-lock type pipe.

In the present embodiment, description is given by taking as an example a case where the emission port 3a of the vapor deposition particle emission portion 3 is provided singly at a center of the upper surface of the vapor deposition particle emission portion 3, however, as long as vapor deposition particles emitted from the emission port 3a of the vapor deposition particle emission portion 3 can be supplied to the plurality of openings 2 of the scan vapor deposition metal mask 1, the position and the number of the emission ports 3a are not limited to such an example.

In the vapor deposition device 10, in the case where the substrate 5 is scanned with respect to the vapor deposition unit 4, the vapor deposition unit 4, i.e., the scan vapor deposition metal mask 1 and the vapor deposition particle emission portion 3, is fixed, and the substrate 5 is moved with respect to the fixed vapor deposition unit 4 in a Y direction (second direction), which is orthogonal to an X direction (first direction) in FIG. 1, i.e., a substrate scanning direction.

The scan vapor deposition is a vapor deposition method in which the scan vapor deposition metal mask 1 smaller than the substrate 5 on which vapor deposition film patterns are to be formed is used to vapor-deposit vapor deposition film patterns on the substrate 5 by scanning (moving) either one of the substrate 5 and the scan vapor deposition metal mask 1 with respect to the other, and the scan vapor deposition metal mask 1 is a metal mask that is used in such scan vapor deposition.

FIG. 2 is a diagram illustrating the scan vapor deposition metal mask 1 provided to the vapor deposition device 10 illustrated in FIG. 1.

As illustrated in FIG. 2, the plurality of openings 2 having an identical shape are formed in the scan vapor deposition metal mask 1.

In first unit opening groups 2a and 2a′ each constituted by three rows×four columns (12) of the openings 2, adjacent openings 2 are arranged at a first opening pitch (first interval) in the X direction and at a second opening pitch (second interval) in the Y direction, and the two first unit opening groups 2a and 2a′ exist in the scan vapor deposition metal mask 1. The two first unit opening groups 2a and 2a′ constitute a second unit opening group 2b.

Accordingly, the plurality of openings 2 having an identical shape and provided in the scan vapor deposition metal mask 1 belong to a single second unit opening group 2b which is constituted by the two first unit opening groups 2a and 2a′.

The two first unit opening groups 2a and 2a′ are arranged by being shifted from each other in the Y direction such that the two first unit opening groups 2a and 2a′ are not adjacent to each other in the X direction, and the two first unit opening groups 2a and 2a′ that are adjacent to each other in the Y direction are arranged such that the first unit opening group 2a′ on an upper side in FIG. 2 is shifted in the X direction from the first unit opening group 2a on a lower side in FIG. 2 by ½ times the first opening pitch (first opening pitch×½).

FIG. 3A to FIG. 3C are diagrams illustrating an example of a process for forming vapor deposition film patterns 6, 7, and 8 on the substrate 5 by using the scan vapor deposition metal mask 1.

FIG. 3A illustrates a case where the scan vapor deposition metal mask 1 is used to form on the substrate 5 the vapor deposition film pattern 6 including a red light-emitting layer corresponding to R pixels of an organic EL display device. FIG. 3B illustrates a case where after the formation, on the substrate 5, of the vapor deposition film pattern 6 that includes the red light-emitting layer corresponding to the R pixels of the organic EL display device, the scan vapor deposition metal mask 1 that has been moved in the X direction by an X-direction subpixel pitch (see FIG. 3C) is used to form on the substrate 5 the vapor deposition film pattern 7 including a green light-emitting layer corresponding to G pixels of the organic EL display device. FIG. 3C illustrates a case where after the formation, on the substrate 5, of the vapor deposition film pattern 7 including the green light-emitting layer corresponding to the G pixels of the organic EL display device, the scan vapor deposition metal mask 1 that has been moved in the X direction by the X-direction subpixel pitch is used to form on the substrate 5 the vapor deposition film pattern 8 including a blue light-emitting layer corresponding to B pixels of the organic EL display device.

Among the 24 openings 2 having an identical shape in the scan vapor deposition metal mask 1, three openings 2 in each column that are arrayed in the Y direction at the second opening pitch in each of the first unit opening groups 2a and 2a′ serve as openings for forming the linear vapor deposition film patterns 6, 7, and 8 that have an identical width in the X direction and each of which is aligned with the Y direction. In other words, the three openings 2 in each column in each of the first unit opening groups 2a and 2a′ serve as openings for forming the linear vapor deposition film patterns 6, 7, and 8 that are provided in continuous fashion from one end to the other end of a display region of the organic EL display device.

As illustrated in FIG. 3A to FIG. 3C, the first opening pitch of the scan vapor deposition metal mask 1 is double an X-direction pitch of the vapor deposition film pattern 6 including the red light-emitting layer, double an X-direction pitch of the vapor deposition film pattern 7 including the green light-emitting layer, and double an X-direction pitch of the vapor deposition film pattern 8 including the blue light-emitting layer, i.e., double an X-direction pixel pitch of the organic EL display device, and the two first unit opening groups 2a and 2a′ that are adjacent to each other in the Y direction are arranged such that the first unit opening group 2a′ on the upper side in the diagrams is shifted in the X direction from the first unit opening group 2a on the lower side in the diagrams by the X-direction pitch of any of the vapor deposition film patterns 6, 7, and 8, i.e., by the X-direction pixel pitch of the organic EL display device.

As described above, each of the vapor deposition film patterns 6, 7, and 8 is formed as a linear pattern, i.e., a stripe pattern, hence the problem, namely the occurrence of jaggies, i.e., straight lines or contours of characters becoming stairlike, and the impossibility to obtain favorable display, are prevented from occurring.

Furthermore, in performing vapor deposition by color of the vapor deposition film patterns 6, 7, and 8, it is sufficient that the substrate 5 is scanned (moved) with respect to the vapor deposition unit 4 in the substrate scanning direction, hence, neither step-wise movement in the X direction and the Y direction nor positioning with high accuracy are needed.

FIG. 4 is a diagram illustrating an interval between adjacent openings 101 in the X direction in a known metal mask 100 and an interval between adjacent openings 2 in the X direction in the scan vapor deposition metal mask 1.

As illustrated in FIG. 4, in a case where the scan vapor deposition metal mask 1 and the known metal mask 100, in which openings 101 are not so arranged as to be shifted in the X direction and the Y direction, are used in an attempt to form vapor deposition film patterns on a substrate with the same density, the first opening pitch, i.e., the interval between adjacent openings 2 in the X direction, in the scan vapor deposition metal mask 1 can be increased to double the interval between an opening 101 and another opening 101 in the known metal mask 100.

Due to limitations in opening positioning accuracy and opening pattern accuracy of a metal mask itself, i.e., limitations in processing accuracy of the metal mask, it is difficult to produce the mask itself with high opening positioning accuracy and high opening pattern accuracy in the case of the known metal mask 100, in which the openings 101 are not so arranged as to be shifted in the X direction and the Y direction, and therefore, it is also difficult to form a high-resolution vapor deposition film that supports 300 ppi or higher on a substrate by using the known metal mask 100.

According to the scan vapor deposition metal mask 1, while maintaining the density of the vapor deposition film patterns formed on a substrate, it is possible to increase the first opening pitch of the scan vapor deposition metal mask 1, i.e., the interval between adjacent openings 2 in the X direction, to such a degree that processing accuracy of the metal mask can be kept high, and therefore, with the use of the scan vapor deposition metal mask 1, which is a metal mask, a high-resolution vapor deposition film that supports 300 ppi or higher can be formed on a substrate.

In a case where, for example, an organic EL display device with 324-ppi resolution is to be produced, the X-direction pixel pitch, the X-direction subpixel pitch, and the Y-direction pixel pitch need to be 78 μm, 26 μm, and 78 μm, respectively, and thus, in such a case, the first opening pitch in the scan vapor deposition metal mask 1 may be formed to be 156 μm, and the two first unit opening groups 2a and 2a′ that are adjacent to each other in the Y direction may be arranged such that the first unit opening group 2a′ on the upper side in the diagram is shifted in the X direction from the first unit opening group 2a on the lower side in the diagram by 78 μm.

In the present embodiment, description is given by taking as an example a case where the number of openings 2 in each column that are arrayed in the Y direction at the second opening pitch in the first unit opening groups 2a and 2a′ is three, however, the number of openings 2 in each column that are arrayed in the Y direction at the second opening pitch and the length of each of the openings 2 in the Y direction are not particularly limited because of the reason described below.

In scan vapor deposition, parameters for determining a film thickness t (Å) of the vapor deposition film patterns 6, 7, and 8 are scanning speed a (mm/s) of the substrate 5 (or the vapor deposition unit 4), a vapor deposition rate b (Å/s), and a total c (mm) of lengths in the Y direction of the openings 2 in each column that are arrayed in the Y direction at the second opening pitch in the first unit opening groups 2a and 2a′ (in the case of the present embodiment, the total of the lengths of the three openings 2 in the Y direction), the film thickness t (Å) of the vapor deposition film patterns 6, 7, and 8 being determined by (Equation 1) below. The vapor deposition rate mentioned above is a speed at which the vapor deposition film patterns 6, 7, and 8 are formed on the substrate 5, the speed being dependent on the amount of vapor deposition particles emitted from the emission port 3a of the vapor deposition particle emission portion 3, and the distance between the substrate 5 and the vapor deposition particle emission portion 3.

t=c×b/a (Equation 1)

Based on the above, the number of openings 2 in each column that are arrayed in the Y direction at the second opening pitch and the length of each of the openings 2 in the Y direction can be determined, as appropriate, in accordance with the film thickness of the vapor deposition film patterns 6, 7, and 8 to be formed on the substrate 5.

In the present embodiment, each of the first unit opening groups 2a and 2a′ is constituted by the openings 2 having an identical shape, however, for the reason described below, each of the first unit opening groups 2a and 2a′ may be constituted by openings having different shapes, as long as X-direction widths of the openings are identical.

According to (Equation 1) above, in a case where the scanning speed a (mm/s) of the substrate 5 (or the vapor deposition unit 4) and the vapor deposition rate b (Å/s) are fixed to be constant, the film thickness t (Å) of the vapor deposition film patterns 6, 7, and 8 is dependent on the total c (mm) of the lengths in the Y direction of the openings 2 in each column that are arrayed in the Y direction at the second opening pitch in the first unit opening groups 2a and 2a′.

Accordingly, in each of the columns laid along the Y direction in the first unit opening groups 2a and 2a′, there may be arranged openings that have an identical width in the X direction but different lengths in the Y direction.

FIG. 5 is a diagram illustrating a modification of the scan vapor deposition metal mask that can be provided to the vapor deposition device 10.

As illustrated in FIG. 5, in a scan vapor deposition metal mask 1a, one opening 9c having a prescribed length in the Y direction is provided in the first column from the left in each of first unit opening groups 9a and 9a′, two openings 9d having a length in the Y direction that is ½ of the prescribed length are provided in the second column from the left, three openings 9e having a length in the Y direction that is ⅓ of the prescribed length are provided in the third column from the left, and four openings 9f having a length in the Y direction that is ¼ of the prescribed length are provided in the fourth column from the left.

Although not illustrated, there may be provided a single opening alone in each of the columns that are laid in the Y direction in the first unit opening groups 2a and 2a′, and such an opening is also referred to as a slit opening. In known high-resolution masks, problems relating to distortion and durability are present when an opening is made into a slit opening. In the scan vapor deposition metal mask 1, however, the first opening pitch, i.e., the interval between adjacent openings 2 in the X direction, can be increased, and the mask is a relatively low-resolution mask, whereby problems relating to distortion and durability are less prone to occur even in a case where an opening is made into a slit opening.

In a case where the scan vapor deposition metal mask 1 is designed such that the total c (mm) of the lengths in the Y direction of the openings 2 in each column that are arrayed in the Y direction at the second opening pitch would be small in order to address the issue of the scan vapor deposition metal mask 1 becoming large-sized due to an increase in mask size in the Y direction, the vapor deposition film patterns 6, 7, and 8 with a prescribed film thickness can be formed without an increase in tact time, by decreasing the scanning speed a (mm/s) of the substrate 5 (or the vapor deposition unit 4) and/or increasing the vapor deposition rate b (Å/s). Meanwhile, in a case where no particular consideration is given to tact time, the number of reciprocations of the substrate 5 (or the vapor deposition unit 4) in the Y direction may be increased. For example, instead of completing the formation of the vapor deposition film patterns 6, 7, and 8 on the substrate 5 through a single scan (single way) of the substrate 5 (or the vapor deposition unit 4), the vapor deposition film patterns 6, 7, and 8 may be formed on the substrate 5 by performing the scan (reciprocation) two or more times.

In the present embodiment, to address the issue of the scan vapor deposition metal mask 1 becoming large-sized due to an increase in mask size in the Y direction, two first unit opening groups 2a and 2a′ are arranged in the Y direction, however, the scan vapor deposition metal mask 1 is not limited to this, and in a case where, for example, a vapor deposition film with higher resolution needs to be formed, the number of first unit opening groups to be arranged in the Y direction may be increased as necessary. This case will be described in detail in another embodiment.

In the present embodiment, description has so far been given mainly of a case where the substrate 5 is scanned (moved) with respect to the vapor deposition unit 4 in the vapor deposition device 10, but in the vapor deposition device 10, the vapor deposition unit 4 may instead be scanned (moved) with respect to the substrate 5.

FIG. 6 is a diagram illustrating an overall configuration of the vapor deposition device 10, the diagram illustrating a case where the vapor deposition unit 4 is scanned with respect to the substrate 5.

As illustrated in FIG. 6, in a case where the vapor deposition unit 4 is scanned with respect to the substrate 5 in the vapor deposition device 10, the substrate 5 is fixed, and the vapor deposition unit 4, i.e., the scan vapor deposition metal mask 1 and the vapor deposition particle emission portion 3, is moved with respect to the fixed substrate 5 in the Y direction, which is orthogonal to the X direction, in FIG. 6, i.e., a vapor deposition unit scanning direction. Note that the scan vapor deposition metal mask 1 and the vapor deposition particle emission portion 3 may either be configured to move together in a unified manner or be configured to move separately.

### Embodiment 2

Next, Embodiment 2 of the disclosure is described on the basis of FIG. 7 and FIG. 8A to FIG. 8C. The present embodiment is different from Embodiment 1 in that the number of first unit opening groups arranged in the Y direction is three, but is otherwise as described in Embodiment 1. For the sake of convenience in a description, each member having the same function as a member illustrated in the diagrams for Embodiment 1 is denoted by the same reference sign, and a description thereof is omitted.

FIG. 7 is a diagram illustrating a scan vapor deposition metal mask 11 that can be provided to the vapor deposition device 10, and FIG. 8A to FIG. 8C illustrate diagrams illustrating an example of a process for forming vapor deposition film patterns 16, 17, and 18 on a substrate 15 by using a scan vapor deposition metal mask 11.

As illustrated in FIG. 7, the plurality of openings 12 that have an identical shape are formed in the scan vapor deposition metal mask 11.

In first unit opening groups 12a, 12a′, and 12a″ each constituted by three rows×three columns (9) of openings 12, adjacent openings 12 are arranged at a first opening pitch in the X direction and at a second opening pitch in the Y direction, and the three first unit opening groups 12a, 12a′, and 12a″ exist in the scan vapor deposition metal mask 11. These three first unit opening groups 12a, 12a′, and 12a″ constitute a second unit opening group 12b.

Accordingly, the plurality of openings 12 having an identical shape and provided in the scan vapor deposition metal mask 11 belong to a single second unit opening group 12b, which is constituted by three first unit opening groups 12a, 12a′, and 12a″.

The three first unit opening groups 12a, 12a′, and 12a″ are arranged by being shifted from each other in the Y direction so as not to be adjacent to each other in the X direction, and the three first unit opening groups 12a, 12a′, and 12a″ that are adjacent to each other in the Y direction are arranged such that the first unit opening group 12a′ in the middle is shifted in the X direction from the first unit opening group 12a on a lower side by ⅓ times the first opening pitch (first opening pitch×⅓) while the first unit opening group 12a″ on an upper side is shifted in the X direction from the first unit opening group 12a′ in the middle by ⅓ times the first opening pitch (first opening pitch×⅓).

FIG. 8A to FIG. 8C illustrates diagrams illustrating an example of a process for forming the vapor deposition film patterns 16, 17, and 18 on the substrate 15 by using the scan vapor deposition metal mask 11.

FIG. 8A illustrates a case where the scan vapor deposition metal mask 11 is used to form on the substrate 15 the vapor deposition film pattern 16 that includes a red light-emitting layer corresponding to R pixels of an organic EL display device. FIG. 8B illustrates a case where after the formation, on the substrate 15, of the vapor deposition film pattern 16 including the red light-emitting layer corresponding to the R pixels of the organic EL display device, the scan vapor deposition metal mask 11 that has been moved in the X direction by an X-direction subpixel pitch (see FIG. 8C) is used to form on the substrate 15 the vapor deposition film pattern 17 that includes a green light-emitting layer corresponding to G pixels of the organic EL display device. FIG. 8C illustrates a case where after the formation, on the substrate 15, of the vapor deposition film pattern 17 including the green light-emitting layer corresponding to the G pixels of the organic EL display device, the scan vapor deposition metal mask 11 that has been moved in the X direction by the X-direction subpixel pitch is used to form on the substrate 15 the vapor deposition film pattern 18 that includes a blue light-emitting layer corresponding to B pixels of the organic EL display device.

Among the 27 openings 12 having an identical shape in the scan vapor deposition metal mask 11, three openings 12 in each column that are arrayed in the Y direction at the second opening pitch in each of the first unit opening groups 12a, 12a′, and 12a″ serve as openings for forming the linear vapor deposition film patterns 16, 17, and 18 that have an identical width in the X direction and each of which is aligned with the Y direction. In other words, the three openings 12 in each column in each of the first unit opening groups 12a, 12a′, and 12a″ serves as openings for forming the linear vapor deposition film patterns 16, 17, and 18 that are provided in continuous fashion from one end to the other end of a display region of the organic EL display device.

As illustrated in FIG. 8A to FIG. 8C, the first opening pitch of the scan vapor deposition metal mask 11 is triple an X-direction pitch of the vapor deposition film pattern 16 including the red light-emitting layer, triple an X-direction pitch of the vapor deposition film pattern 17 including the green light-emitting layer, and triple an X-direction pitch of the vapor deposition film pattern 18 including the blue light-emitting layer, i.e., triple an X-direction pixel pitch of the organic EL display device, and the three first unit opening groups 12a, 12a′, and 12a″ that are adjacent to each other in the Y direction are arranged such that the first unit opening group 12a′ in the middle is shifted in the X direction from the first unit opening group 12a on the lower side by the X-direction pitch of any of the vapor deposition film patterns 16, 17, and 18, i.e., by the X-direction pixel pitch of the organic EL display device while the first unit opening group 12a″ on the upper side is shifted in the X direction from the first unit opening group 12a′ in the middle by the X-direction pitch of any of the vapor deposition film patterns 16, 17, and 18, i.e., by the X-direction pixel pitch of the organic EL display device.

In order to address the issue of the scan vapor deposition metal mask 11 becoming large-sized due to an increase in mask size in the Y direction since the three first unit opening groups 12a, 12a′, and 12a″ are arranged in the Y direction, the scan vapor deposition metal mask 11 is preferably designed such that a total c (mm) of the lengths in the Y direction of the openings 12 in each column that are arrayed in the Y direction in each of the first unit opening groups 12a, 12a′, and 12a″ at the second opening pitch would be small.

In such a case, by decreasing the scanning speed a (mm/s) of the substrate 15 (or the vapor deposition unit 4) and/or increasing a vapor deposition rate b (Å/s), the vapor deposition film patterns 16, 17, and 18 with a prescribed film thickness can be formed without an increase in tact time. In a case where the tact time does not need to be particularly taken into consideration, the number of reciprocations of the substrate 15 (or the vapor deposition unit 4) in the Y direction may be increased.

Note that, in the present embodiment, description is given by taking as an example a case where the number of openings 12 is the same, i.e., nine, among the first unit opening groups 12a, 12a′, and 12a″, however, the openings 12 are not limited to this, and the number of openings 12 may be different among the first unit opening groups 12a, 12a′, and 12a″.

For example, in a case where the three openings 21 arranged in the rightmost column are not needed in the first unit opening group 12a″ on the upper side in the scan vapor deposition metal mask 11, in view of forming unnecessary vapor deposition patterns as little as possible, or the like, the first unit opening group 12a″ on the upper side of the scan vapor deposition metal mask 11 may be constituted by three columns×two rows (six) of the openings 12, different from the first unit opening group 12a′ in the middle and the first unit opening group 12a on the lower side.

In the present embodiment, to enable formation of a higher-resolution vapor deposition film, the number of first unit opening groups arranged in the Y direction is three, however, the number is not limited to this and may be determined appropriately by taking into consideration of the density of the vapor deposition film to be formed on the substrate and the mask size.

By taking account only of the mask size, the number of first unit opening groups arranged in the Y direction is preferably two as in Embodiment 1 described above. However, in this case, due to a problem of the opening positioning accuracy and the pattern accuracy of a metal mask, there is a possibility of not being able to manufacture a mask with which an ultra-high-resolution vapor deposition film can be formed on a substrate. However, in a case where the number of first unit opening groups arranged in the Y direction is increased, the mask size in the Y direction increases proportionally, resulting in an increase in size of the entire mask. To address this issue, in the present embodiment, the number of first unit opening groups arranged in the Y direction is set at three.

In a case where the number of first unit opening groups is three or greater, the scan vapor deposition metal mask 11 is preferably designed such that the total c (mm) of the lengths in the Y direction of the openings 12 in each column that are arrayed in the Y direction at the second opening pitch would be small in order to address the issue of the scan vapor deposition metal mask 11 becoming large-sized due to an increase in mask size in the Y direction.

In such a case, by decreasing the scanning speed a (mm/s) of the substrate 15 (or the vapor deposition unit 4) and/or increasing a vapor deposition rate b (Å/s), the vapor deposition film patterns 16, 17, and 18 with a prescribed film thickness can be formed without an increase in tact time. Meanwhile, in a case where no particular consideration is given to tact time, the number of reciprocations of the substrate 15 (or the vapor deposition unit 4) in the Y direction may be increased. For example, instead of completing the formation of the vapor deposition film patterns 16, 17, and 18 on the substrate 15 through a single scan (single way) of the substrate 15 (or the vapor deposition unit 4), the vapor deposition film patterns 16, 17, and 18 may be formed on the substrate 15 by performing the scan (reciprocation) two or more times.

### Embodiment 3

Next, Embodiment 3 of the disclosure is described on the basis of FIG. 9. The present embodiment is different from Embodiments 1 and 2 in that a second opening pitch between openings 22 is set greater, but is otherwise as described in Embodiments 1 and 2. For the sake of convenience in description, each member having the same function as a member illustrated in the diagrams for Embodiments 1 and 2 is denoted by the same reference sign, and a description thereof is omitted.

FIG. 9A illustrates a diagram illustrating a scan vapor deposition metal mask 21, and FIG. 9B illustrates a diagram illustrating an example of a process for forming vapor deposition film patterns 26, 27, and 28 on a substrate 25 by using the scan vapor deposition metal mask 21.

As illustrated in FIG. 9, the plurality of openings 22 that have an identical shape are formed in the scan vapor deposition metal mask 21.

In first unit opening groups 22a and 22a′ each constituted by three rows×four columns (12) of the openings 22, adjacent openings 22 are arranged at a first opening pitch in the X direction and at a second opening pitch in the Y direction. The second opening pitch is set to be equal to or greater than the first opening pitch, and the interval (bridge width (metal part)) between the openings 22 adjacent to each other in the Y direction is set to be equal to or greater than the interval (bridge width (metal part)) between the openings 22 adjacent to each other in the X direction. Note that, in FIG. 9A, the 12 openings 22 belonging to the first unit opening group 22a are illustrated in solid lines, and the twelve openings 22 belonging to the first unit opening group 22a′ are illustrated in dotted lines. Accordingly, the two first unit opening groups 22a and 22a′ exist in the scan vapor deposition metal mask 21, and the two first unit opening groups 22a and 22a′ constitute a second unit opening group.

Accordingly, the plurality of openings 22 having an identical shape and provided in the scan vapor deposition metal mask 21 belong to a single second unit opening group, which is constituted by the two first unit opening groups 22a and 22a′.

The two first unit opening groups 22a and 22a′ are arranged by being shifted from each other in the Y direction so as not to be adjacent to each other in the X direction, and the two first unit opening groups 22a and 22a′ that are adjacent to each other in the Y direction are arranged by being shifted in the X direction by ½ times the first opening pitch (first opening pitch×½).

One of the reasons why high-resolution masks cannot be manufactured for known metal masks is that the bridge width (metal part) between mask openings is small. In the scan vapor deposition metal mask 21, although the number of openings 22 in each of the first unit opening groups 22a and 22a′ is the same as the number of openings 2 in each of the first unit opening groups 2a and 2a′ in the scan vapor deposition metal mask 1 of Embodiment 1 described above, the X-direction bridge width of the scan vapor deposition metal mask 21 is the same as the X-direction bridge width of the scan vapor deposition metal mask 1 while the Y-direction bridge width of the scan vapor deposition metal mask 21 is greater than the Y-direction bridge width of the scan vapor deposition metal mask 1.

As described above, the Y-direction bridge width, i.e., the second opening pitch, can be set to be large in the scan vapor deposition metal mask 21, because, in a case where a scanning speed a (mm/s) of the substrate 25 (or the vapor deposition unit 4) and a vapor deposition rate b (Å/s) are constant, the film thickness of the vapor deposition film patterns 26, 27, and 28 to be formed on the substrate 25 is determined by a total c (mm) of the lengths in the Y direction of the openings 22 in each column that are arrayed in the Y direction at the second opening pitch in each of the first unit opening groups 22a and 22a′.

Hence, using the arrangement of the openings 22 in the scan vapor deposition metal mask 21 can secure sufficient bridge widths in both the X direction and the Y direction without causing the mask to become large-sized.

Moreover, using the arrangement of the openings 22 in the scan vapor deposition metal mask 21 can decrease the vapor deposition time lag of the vapor deposition film patterns in comparison with the scan vapor deposition metal mask 1 (see FIG. 2) of Embodiment 1 described above and the scan vapor deposition metal mask 11 (see FIG. 7) of Embodiment 2 described above. For example, in the scan vapor deposition metal mask 11 (see FIG. 7), in the case of performing vapor deposition while moving the substrate 15 from a lower direction of the diagram to an upper direction of the diagram, a vapor deposition film pattern corresponding to the first unit opening group 12a on the lower side is first formed on the substrate 15, thereafter a vapor deposition film pattern corresponding to the first unit opening group 12a′ in the middle is formed, and lastly a vapor deposition film pattern corresponding to the first unit opening group 12a″ on an upper side is formed. Hence, the vapor deposition time lag of the vapor deposition film patterns results in being long although the vapor deposition film patterns include light-emitting layers of the same color.

For example, in a case where impurities, such as contamination (also call “contami” in some cases), accumulate in a vapor deposition room, and the impurities constantly reach a film formation surface of a substrate, the state of formation of an impurity layer varies between the upstream (the vapor deposition film pattern corresponding to the first unit opening group 12a on the lower side) and the downstream (the vapor deposition film pattern corresponding to the first unit opening group 12a″ on the upper side) when the vapor deposition time lag of vapor deposition film patterns is long as described above, which causes a difference in luminance and leads to the possibility of causing poor light emission. In contrast, the difference in luminance can be reduced as the vapor deposition time lag of the vapor deposition film patterns is shorter, which makes poor light emission less likely to occur.

As illustrated in FIG. 9B, among the 24 openings 22 having an identical shape in the scan vapor deposition metal mask 21, three openings 22 in each column that are arrayed in the Y direction at the second opening pitch in each of the first unit opening groups 22a and 22a′ serve as openings for forming the linear vapor deposition film patterns 26, 27, and 28 that have an identical width in the X direction and each of which is aligned with the Y direction. In other words, the three openings 22 in each column in each of the first unit opening groups 22a and 22a′ serve as openings for forming the linear vapor deposition film patterns 26, 27, and 28 that are provided in continuous fashion from one end to the other end of a display region of the organic EL display device.

The first opening pitch of the scan vapor deposition metal mask 21 is double an X-direction pitch of the vapor deposition film pattern 26 including the red light-emitting layer, double an X-direction pitch of the vapor deposition film pattern 27 including the green light-emitting layer, and double an X-direction pitch of the vapor deposition film pattern 28 including the blue light-emitting layer, i.e., double an X-direction pixel pitch of the organic EL display device, and the two first unit opening groups 22a and 22a′ that are adjacent to each other in the Y direction are arranged by being shifted in the X direction from each other by the X-direction pitch of any of the vapor deposition film patterns 26, 27, and 28, i.e., by the X-direction pixel pitch of the organic EL display device.

### Embodiment 4

Next, Embodiment 4 of the disclosure is described on the basis of FIG. 10 to FIG. 12. The present embodiment is different from Embodiments 1 to 3 in that the number and shape of openings in a scan vapor deposition metal mask are optimized by taking account of direction distribution (an N value as a parameter representing directivity) occurring in vapor deposition particles emitted from the emission port 3a of the vapor deposition particle emission portion 3 illustrated in FIG. 1, but is otherwise as described in Embodiments 1 to 3. For the sake of convenience in a description, each member having the same function as a member illustrated in the diagrams for Embodiments 1 to 3 is denoted by the same reference sign, and a description thereof is omitted.

FIG. 10 is a diagram for describing a film thickness distribution that can occur according to the distance from the emission port 3a of the vapor deposition particle emission portion 3 in a case where vapor deposition film patterns are formed on a substrate by using the scan vapor deposition metal mask 1 illustrated in FIG. 2.

As illustrated in FIG. 10, the film thickness of the vapor deposition film pattern immediately above the emission port 3a is the greatest, and the film thickness decreases as the vapor deposition film pattern is farther from the emission port 3a. Such a film thickness distribution in the single substrate occurs due to a direction distribution occurring in vapor deposition particles emitted from the emission port 3a of the vapor deposition particle emission portion 3 (the N value as a parameter representing directivity obtained by converting this distribution into numbers).

Accordingly, in a case of the scan vapor deposition metal mask 1, in which a total c (mm) of the lengths in the Y direction of the three openings 2 in each column that are arrayed in the Y direction is set to be constant, a difference in film thickness may occur between vapor deposition film patterns immediately above the emission port 3a and a position farther from the position immediately above the emission port 3a. Such a film thickness distribution within one substrate may cause unevenness in light emission depending on a vapor deposition material to be used and is therefore preferably reduced to realize a higher picture quality of the organic EL display device.

FIG. 11 is a diagram illustrating a scan vapor deposition metal mask 31 and a film thickness distribution that can occur according to the distance from the emission port 3a of the vapor deposition particle emission portion 3 in a case where vapor deposition film patterns are formed on a substrate by using the scan vapor deposition metal mask 31.

In the case of the scan vapor deposition metal mask 31, the film thickness distribution within one single substrate is improved by increasing the total c (mm) of the lengths in the Y direction of the three openings in each column that are arranged in the Y direction as the three openings are farther from the emission port 3a of the vapor deposition particle emission portion 3.

Four kinds of openings 32c, 32d, 32e, and 32f in the scan vapor deposition metal mask 31 have the same width in the X direction while being different only in length in the Y direction.

As illustrated in FIG. 11, the openings 32c arranged at the closest position to the emission port 3a of the vapor deposition particle emission portion 3 have the smallest length in the Y direction and hence have the smallest total c (mm) of the lengths in the Y direction of the three openings 32c arrayed in the Y direction. The openings 32d arranged at the second closest position to the emission port 3a of the vapor deposition particle emission portion 3 have a length in the Y direction that is greater than the length in the Y direction of the openings 32c, and hence the total c (mm) of the lengths in the Y direction of the three openings 32d arrayed in the Y direction, is greater than the total c (mm) of the lengths in the Y direction of the three openings 32c arrayed in the Y direction. The openings 32e arranged at the third closest position to the emission port 3a of the vapor deposition particle emission portion 3 have a length in the Y direction that is greater than the length in the Y direction of the openings 32d, and hence the total c (mm) of the lengths in the Y direction of the three openings 32d arrayed in the Y direction is greater than the total c (mm) of the lengths in the Y direction of the three openings 32c arrayed in the Y direction. The openings 32f arranged at the farthest position from the emission port 3a of the vapor deposition particle emission portion 3 have a length in the Y direction that is greater than the length in the Y direction of the openings 32e, and hence the total c (mm) of the lengths in the Y direction of the three openings 32f arrayed in the Y direction is greater than the total c (mm) of the lengths in the Y direction of the three openings 32e arrayed in the Y direction.

In first unit opening groups 32a and 32a′ each constituted by three rows×four columns (12) of the openings 32c, 32d, 32e, and 32f of four kinds, adjacent openings are arranged at a first opening pitch (first interval) in the X direction, and the two first unit opening groups 32a and 32a′ exist in the scan vapor deposition metal mask 31. These two first unit opening groups 32a and 32a′ constitute a second unit opening group 32b.

Accordingly, the openings 32c, 32d, 32e, and 32f provided in the scan vapor deposition metal mask 31 belong to a single second unit opening group 32b that is constituted by two first unit opening groups 32a and 32a′.

The two first unit opening groups 32a and 32a′ are arranged by being shifted from each other in the Y direction such that the two first unit opening groups 32a and 32a′ are not adjacent to each other in the X direction, and the two first unit opening groups 32a and 32a′ that are adjacent to each other in the Y direction are arranged such that the first unit opening group 32a′ on an upper side in the diagram is shifted in the X direction from the first unit opening group 32a on a lower side in the diagram by ½ times the first opening pitch (first opening pitch×½).

FIG. 12 is a diagram illustrating a scan vapor deposition metal mask 41 and a film thickness distribution that can occur according to the distance from the emission port 3a of the vapor deposition particle emission portion 3 in a case where vapor deposition film patterns are formed on a substrate by using the scan vapor deposition metal mask 41.

In the scan vapor deposition metal mask 41, openings 42 having an identical shape are formed, and the film thickness distribution within one substrate is improved by increasing a total c (mm) of the lengths in the Y direction of openings 42 in each column that are arrayed in the Y direction as the openings 42 are farther from the emission port 3a of the vapor deposition particle emission portion 3, by increasing the number of openings 42 as the openings 42 are farther from the emission port 3a of the vapor deposition particle emission portion 3.

As illustrated in FIG. 12, two openings 42 are arranged at the closest position to the emission port 3a of the vapor deposition particle emission portion 3, and thus a total c (mm) of the lengths in the Y direction of the two openings 42 arrayed in the Y direction is the smallest. Three openings 42 are arranged at the second closest position to the emission port 3a of the vapor deposition particle emission portion 3, and thus, a total c (mm) of the lengths in the Y direction of the three openings 42 arrayed in the Y direction is greater than the total c (mm) of the lengths in the Y direction of the two openings 42 arrayed in the Y direction. Four openings 42 are arranged at the third closest position to the emission port 3a of the vapor deposition particle emission portion 3, and thus, a total c (mm) of the lengths in the Y direction of the four openings 42 arrayed in the Y direction is greater than the total c (mm) of the lengths in the Y direction of the three openings 42 arrayed in the Y direction. Five openings 42 are arranged at the farthest position from the emission port 3a of the vapor deposition particle emission portion 3, and thus, a total c (mm) of the lengths in the Y direction of the five openings 42 arrayed in the Y direction is greater than the total c (mm) of the lengths in the Y direction of the four openings 42 arrayed in the Y direction.

In first unit opening groups 42a and 42a′ each constituted by 14 openings, adjacent openings are arranged at a first opening pitch (first interval) in the X direction, and the two first unit opening groups 42a and 42a′ exist in the scan vapor deposition metal mask 41. These two first unit opening groups 42a and 42a′ constitute a second unit opening group 42b.

Accordingly, the 28 openings 42 provided in the scan vapor deposition metal mask 41 belong to a single second unit opening group 42b, which is constituted by the two first unit opening groups 42a and 42a′.

The two first unit opening groups 42a and 42a′ are arranged by being shifted from each other in the Y direction such that the two first unit opening groups 42a and 42a′ are not adjacent to each other in the X direction, and the two first unit opening groups 42a and 42a′ that are adjacent to each other in the Y direction are arranged such that the first unit opening group 42a′ on an upper side in the diagram is shifted in the X direction from the first unit opening group 42a on a lower side in the diagram by ½ times the first opening pitch (first opening pitch×½).

### Embodiment 5

Next, Embodiment 5 of the disclosure is described on the basis of FIG. 13 to FIG. 15 and FIG. 18. The present embodiment is different from Embodiments 1 to 4 in that a scan vapor deposition metal mask 51 is a relatively large-sized mask that can operate with a vapor deposition particle emission portion 54 in which a plurality of emission ports 54a are formed, but is otherwise as described in Embodiments 1 to 4. For the sake of convenience in a description, each member having the same function as a member illustrated in the diagrams for Embodiments 1 to 4 is denoted by the same reference sign, and a description thereof is omitted.

FIG. 13 is a diagram illustrating an overall configuration of the vapor deposition device 50, the diagram illustrating a case where a substrate 56 is scanned (moved) with respect to a vapor deposition unit 55.

As illustrated in FIG. 13, the vapor deposition device 50 includes the vapor deposition unit 55 and the substrate 56.

The vapor deposition unit 55 includes the scan vapor deposition metal mask 51 in which openings 52 are formed, a restriction plate (restriction plate unit) 53 in which a plurality of through holes 53a and 53b are formed, and a vapor deposition particle emission portion 54 in which a plurality of emission ports 54a configured to emit vapor deposition particles are provided.

In the vapor deposition unit 55, the vapor deposition particle emission portion 54, the restriction plate 53, and the scan vapor deposition metal mask 51 are arranged in this order from the bottom so as to overlap each other in plan view.

In the restriction plate 53, each one of the through holes 53a and 53b is formed at the position facing a corresponding one of the second unit opening groups 52b of the scan vapor deposition metal mask 51, the plurality of through holes 53a formed on a lower side with respect to an emission port reference line and the plurality of through holes 53b formed on an upper side of the emission line reference line are arranged alternately by being shifted from each other in the Y direction, the emission port reference line corresponding to the plurality of emission ports 54a emitting vapor deposition particles arranged in the X direction and overlapping the restriction plate 53 in plan view. In other words, in the restriction plate 53, the plurality of through holes 53a and the plurality of through holes 53b are arranged in a staggered manner with respect to the emission port reference line.

Accordingly, the vapor deposition particles emitted from each one of the emission ports 54a of the vapor deposition particle emission portion 54 pass through a corresponding one of the through holes 53a and 53b of the restriction plate 53 positioned on the lower and upper portion immediately above, and are then supplied to the one second unit opening groups 52b of the scan vapor deposition metal mask 51, the one second unit opening group 52b being positioned immediately above the corresponding one of the through holes 53a and 53b.

Such a configuration can prevent the vapor deposition particles (vapor deposition flow) emitted from the plurality of emission ports 54a of the vapor deposition particle emission portion 54 from spreading out and the vapor deposition particles emitted from two adjacent emission ports 54a from interfering with each other in the scan vapor deposition metal mask 51.

The restriction plate 53 provided with the plurality of through holes 53a and 53b restricts the incident angle of vapor deposition particles to the scan vapor deposition metal mask 51 within a certain range, the vapor deposition particles being emitted from each of the plurality of emission ports 54a of the vapor deposition particle emission portion 54 and diffused (vapor deposition particles outside the certain range physically attach to the restriction plate 53), and the restriction plate 53 prevents vapor deposition particles from attaching to the substrate 56 from any oblique direction. Note that the plurality of through holes 53a and 53b are provided so as to correspond to the plurality of respective emission ports 54a of the vapor deposition particle emission portion 54.

Each of the plurality of emission ports 54a of the vapor deposition particle emission portion 54 is arranged at a position where the vapor deposition particles can be supplied to each of the (24) openings 52 of the corresponding one of the second unit opening groups 52b of the scan vapor deposition metal mask 51 through the corresponding one of the through holes 53a and 53b.

As described above, the vapor deposition device 50 includes the scan vapor deposition metal mask 51, the vapor deposition particle emission portion 54 including the plurality of emission ports 54a configured to emit vapor deposition particles, the restriction plate 53 provided between the scan vapor deposition metal mask 51 and the vapor deposition particle emission portion 54, and the substrate 56 on which vapor deposition particles emitted from the emission ports 54a of the vapor deposition particle emission portion 54 are vapor-deposited through the restriction plate 53 and the scan vapor deposition metal mask 51. In the restriction plate 53, the through holes 53a and 53b for restricting the incident angle of vapor deposition particles to the scan vapor deposition metal mask 51 within the certain range, the vapor deposition particles being emitted from the plurality of respective emission ports 54a, are arranged by being shifted from each other in the Y direction so as to face the respective second unit opening groups 52b of the scan vapor deposition metal mask 51. The vapor deposition particles emitted from each of the plurality of emission ports 54a are supplied to the corresponding one of the openings 52 in the corresponding one of the second opening groups 52b immediately above the corresponding one of the through holes 53a and 53b, through the corresponding one of the through holes 53a and 53b arranged above.

In the vapor deposition device 50, in the case where the substrate 56 is scanned with respect to the vapor deposition unit 55, the vapor deposition unit 55, i.e., the scan vapor deposition metal mask 51, the restriction plate 53, and the vapor deposition particle emission portion 54, is fixed, and the substrate 56 is moved with respect to the fixed vapor deposition unit 55 in the Y direction, which is orthogonal to the X direction in FIG. 13, i.e., a substrate scanning direction.

As described above, since the plurality of emission ports 54a are provided to the vapor deposition particle emission portion 54 and the plurality of through holes 53a and 53b corresponding to the plurality of emission ports 54a are provided in the restriction plate 53, the scan vapor deposition metal mask 51 can operate with the substrate 56 that is greater in size, by arranging the openings 52 such that the openings 52 correspond to the emission ports 54a and the through holes 53a and 53b in the scan vapor deposition metal mask 51.

In the scan vapor deposition metal mask 51, the plurality of second unit opening groups 52b, each of which is constituted by the 24 openings 52, are arranged in a staggered manner so as to face the plurality of through holes 53a and the plurality of through holes 53b arranged in a staggered manner in the restriction plate 53.

FIG. 14 is a diagram illustrating an example of a process for forming vapor deposition film patterns 57, 58, and 59 on the substrate 56 by using the scan vapor deposition metal mask 51.

As illustrated in FIG. 14, the plurality of openings 52 that have an identical shape are formed in the scan vapor deposition metal mask 51.

In first unit opening groups 52a and 52a′ each constituted by three rows×four columns (12) of the openings 52, each two adjacent openings 52 are arranged at a first opening pitch in the X direction and at a second opening pitch in the Y direction. The first unit opening groups 52a and 52a′ constitute the second unit opening group 52b, and the plurality of second unit opening groups 52b are arranged in a staggered manner alternately on the upper side and the lower side with the emission port reference line in the middle, as described above.

Accordingly, the plurality of openings 52 having an identical shape and provided in the scan vapor deposition metal mask 51 belong to the plurality of second unit opening groups 52b, each of which is constituted by the two first unit opening groups 52a and 52a′.

The two first unit opening groups 52a and 52a′ are arranged by being shifted from each other in the Y direction so as not to be adjacent to each other in the X direction, and each two first unit opening groups 52a and 52a′ that are adjacent to each other in the Y direction are arranged by being shifted in the X direction by ½ times the first opening pitch (first opening pitch×½).

Among the openings 52 having an identical shape in the scan vapor deposition metal mask 51, three openings 52 in each column that are arrayed in the Y direction at the second opening pitch in each of the first unit opening groups 52a and 52a′ belonging to each of the second unit opening groups 52b serve as openings for forming the linear vapor deposition film patterns 57, 58, and 59 that have an identical width in the X direction and each of which is aligned with the Y direction. In other words, the three openings 52 in each column in each of the first unit opening groups 52a and 52a′ serve as openings for forming the linear vapor deposition film patterns 57, 58, and 59 that are provided in continuous fashion from one end to the other end of a display region of the organic EL display device.

As illustrated in FIG. 14, the first opening pitch of the scan vapor deposition metal mask 51 is double an X-direction pitch of the vapor deposition film pattern 57 including the red light-emitting layer, double an X-direction pitch of the vapor deposition film pattern 58 including the green light-emitting layer, and double an X-direction pitch of the vapor deposition film pattern 59 including the blue light-emitting layer, i.e., double an X-direction pixel pitch of the organic EL display device, and each two first unit opening groups 52a and 52a′ adjacent to each other in the Y direction are arranged by being shifted in the X direction from each other by the X-direction pitch of any of the vapor deposition film patterns 57, 58, and 59, i.e., by the X-direction pixel pitch of the organic EL display device.

The size of the scan vapor deposition metal mask 51, which is a relatively large-sized mask, is still smaller than the size of the substrate 56.

FIG. 15 is a diagram illustrating a scan vapor deposition metal mask 51a, which is a comparative example.

In a case where the vapor deposition device 50 does not include the restriction plate 53, which plays a role for controlling diffusion of vapor deposition particles emitted from each of the plurality of emission ports 54a of the vapor deposition particle emission portion 54 and increasing the directivity of the flow of vapor deposition particles (vapor deposition flow), the flows of vapor deposition particles (vapor deposition flow) emitted from the plurality of emission ports 54a and to be diffused interfere with each other, which prevents normal vapor deposition.

Even in a case of including a restriction plate, when through holes are formed and arranged at a regular interval in the X direction unlike the restriction plate 53, in which the through holes 53a and 53b are arranged in a staggered manner, the flows of vapor deposition particles (vapor deposition flows) emitted from the plurality of emission ports 54a and to be diffused interfere with each other, which prevents normal vapor deposition.

For example, in a case where through holes in a restriction plate are formed and arranged at a regular interval in the X direction and a case of the scan vapor deposition metal mask 51a in which the plurality of second unit opening groups 52b are arranged only on one side with respect to an emission port reference line in the middle so as to correspond to the through holes formed at a regular interval in the X direction, instead of a staggered manner, the following problem may occur.

In a case where the restriction plate is designed such that each of the through holes formed at a regular interval in the X direction restricts the incident angle of vapor deposition particles to the scan vapor deposition metal mask 51a within a certain range, the vapor deposition particles being emitted from each of the plurality of emission ports 54a and diffused, while the through holes formed at a regular interval in the X direction enable the flows of the vapor deposition particles (vapor deposition flows) emitted from the plurality of emission ports 54a to diffuse exactly to the X-direction end portions of the corresponding one of the plurality of second unit opening groups 52b, there is no margin, and hence the through holes are generally designed to be formed at a regular interval in the X direction such that the flows of vapor deposition particles (vapor deposition flows) emitted from each of the plurality of emission ports 54a would be diffused to the outside the X-direction end portions of the corresponding one of the plurality of second unit opening groups 52b.

Since the through holes formed at a regular interval in the X direction are generally designed as described above, in a case of the scan vapor deposition metal mask 51a, in which the plurality of second unit opening groups 52b are arranged only on one side with respect to the emission port reference line in the middle, a joint portion is formed at the boundary portion between each two adjacent second unit opening groups 52b affected by the flows of vapor deposition particles (vapor deposition flows) passing through adjacent through holes formed at a regular interval in the X direction. Using the openings 52 positioned at each joint portion prevents normal vapor deposition, which may cause unevenness.

In the case of the vapor deposition device 50 illustrated in FIG. 13 and including the scan vapor deposition metal mask 51, in which the plurality of second unit opening groups 52b are arranged in a staggered manner, and the restriction plate 53, in which the through holes 53a and 53b are arranged in a staggered manner, no above-described joint portions are formed, and hence the problem of unevenness can be solved.

FIG. 18 is a diagram illustrating an overall configuration of an organic EL display device 70 including the substrate 56 illustrated in FIG. 14, on which the vapor deposition film patterns 57, 58, and 59 are formed.

As illustrated in FIG. 18, in the organic EL display device (electroluminescence display device) 70, the substrate 56, on which the vapor deposition film patterns 57, 58, and 59 are formed, and a sealing substrate 67 are attached to each other with sealing resin 66. Note that the sealing resin 66 is formed on end portions of the four sides of the substrate 56, on which the vapor deposition film patterns 57, 58, and 59 are formed.

Note that, on the substrate 56, the vapor deposition film patterns 57, 58, and 59 are formed between a negative electrode and a positive electrode, which are not illustrated.

### Embodiment 6

Next, Embodiment 6 of the disclosure is described on the basis of FIG. 16 and FIG. 17. The present embodiment is different from Embodiment 5 in that in a vapor deposition device 65 a plurality of emission ports 64a and 64b of a vapor deposition particle emission portion 64 are arranged at respective substantially central portions of the plurality of second unit opening groups 52b of the scan vapor deposition metal mask 51, but is otherwise as described in Embodiment 5. For the sake of convenience in a description, each member having the same function as a member illustrated in the diagrams for Embodiment 5 is denoted by the same reference sign, and a description thereof is omitted.

FIG. 16 is a diagram illustrating an overall configuration of the vapor deposition device 65, and no substrate is illustrated.

As illustrated in the diagram, the vapor deposition device 65 includes a vapor deposition unit, and the vapor deposition unit includes the scan vapor deposition metal mask 51, in which the openings 52 are formed, the restriction plate (restriction plate unit) 53, in which the plurality of through holes 53a and 53b are formed, and the vapor deposition particle emission portion 64 in which the plurality of emission ports 64a and 64b are arranged in a staggered manner so as to be positioned at respective substantial centers of the through holes 53a and 53b.

In other words, the plurality of emission ports 64a and 64b of the vapor deposition particle emission portion 64 are arranged by being alternately shifted in the Y direction so as to be positioned at the respective substantial centers of the through holes 53a and 53b.

In the restriction plate 53, the plurality of through holes 53a formed on a lower side of an emission port reference line and the plurality of through holes 53b formed on an upper side of the emission port reference line are arranged by being shifted from each other in the Y direction, the emission port reference line being a Y-direction center line of the emission ports 64a and the emission ports 64b overlapping the restriction plate 53 in plan view.

Accordingly, vapor deposition particles (vapor deposition flow) emitted from one of the emission ports 64a and 64b of the vapor deposition particle emission portion 64 pass through a corresponding one of the through holes 53a and 53b of the restriction plate 53 positioned immediately above, and are supplied to a corresponding one of the second unit opening groups 52b of the scan vapor deposition metal mask 51 positioned immediately above.

Note that, in the present embodiment, description is given by taking as an example a case of the scan vapor deposition metal mask in which the total c (mm) of the lengths in the Y direction of the three openings 52 in each column that are arrayed in the Y direction is set to be constant. However, from the viewpoint of reducing a film thickness distribution within one substrate, the total c (mm) of the lengths in the Y direction of the openings in each column that are arrayed in the Y direction may be set greater as the openings are farther from the emission ports 64a and 64b of the vapor deposition particle emission portion 54, in each of the second unit opening groups 52b of the scan vapor deposition metal mask 51 as described in Embodiment 4 described above.

FIG. 17 is a diagram illustrating the positions of the plurality of emission ports 64a and 64b of the vapor deposition particle emission portion 64 that correspond to the respective positions of the plurality of second unit opening groups 52b of the scan vapor deposition metal mask 51.

As illustrated in FIG. 17, the plurality of emission ports 64a and 64b of the vapor deposition particle emission portion 64 are arranged at the respective centers of the positions of the plurality of second unit opening groups 52b of the scan vapor deposition metal mask 51, and hence an area with the highest density of vapor deposition particles can be used, which can reduce the tact time.

### Supplement

A scan vapor deposition metal mask according to aspect 1 of the disclosure includes a plurality of openings formed into an identical width in a first direction. Each of first unit opening groups is constituted by part of the plurality of openings, each two of the part of the plurality of openings adjacent to each other in the first direction being arranged at a first interval from each other, one or more of the part of the plurality of openings being arrayed in a second direction orthogonal to the first direction. The plurality of openings belong to one or more second unit opening groups each constituted by N (N is an integer of two or more) of the first unit opening groups. The N first unit opening groups are arranged by being shifted from each other in the second direction, the first unit opening groups not being adjacent to each other in the first direction, while each two of the first unit opening groups adjacent to each other in the second direction are arranged by being shifted from each other in the first direction by 1/N times the first interval. In each of the first unit opening groups, one or more openings of the plurality openings arrayed in the second direction serve as openings for forming a linear vapor deposition film pattern having an identical width in the first direction and aligned with the second direction.

According to the above configuration, in each of the first unit opening groups, the one or more openings arrayed in the second direction are one or more openings for forming a linear vapor deposition film pattern having an identical width in the first direction and aligned with the second direction, the N first unit opening groups (N is an integer of two or more) are included, and the N first unit opening groups are arranged by being shifted from each other in the second direction such that the first unit opening groups are not to be adjacent from each other in the first direction, while the first unit opening groups adjacent to each other in the second direction are arranged by being shifted from each other in the first direction by 1/N times the first interval.

Hence, in a case of attempting to form, on a substrate, vapor deposition film patterns with the same density by using the scan vapor deposition metal mask, in which the arrangement of the openings is improved as described above, and a known metal mask in which openings are not arranged by being shifted in the first direction and the second direction, it is possible, with the scan vapor deposition metal mask, to increase the first interval, i.e., the interval between adjacent openings in the first direction, to N times the interval between openings in the known metal mask, and hence to fulfill high opening positioning accuracy and high opening pattern accuracy although the scan vapor deposition metal mask is a metal mask.

Hence, with the above configuration, it is possible to provide a scan vapor deposition metal mask with which a high-resolution, linear vapor deposition film pattern can be formed even on a large-sized substrate.

In a scan vapor deposition metal mask according to aspect 2 of thedisclosure, the N is preferably 2 in aspect 1 described above.

With the above configuration, it is possible to provide a relatively small-sized scan vapor deposition metal mask with which a high-resolution, linear vapor deposition film pattern can be formed even on a large-sized substrate and which is not large in width in the second direction.

In a scan vapor deposition metal mask according to aspect 3 of the disclosure, the N is preferably 3 in aspect 1 described above.

With the above configuration, it is possible to provide a scan vapor deposition metal mask with which a higher-resolution, linear vapor deposition film pattern can be formed on a large-sized substrate.

In a scan vapor deposition metal mask according to aspect 4 of the disclosure, the total length, in the second direction, of the one or more openings arrayed in the second direction is preferably greater as the one or more openings arrayed in the second direction are farther from the center in the first direction, in any of aspects 1 to 3 described above.

With the above configuration, it is possible to provide a scan vapor deposition metal mask with which higher-resolution, linear vapor deposition film patterns with a further even film thickness can be formed on a substrate.

In a scan vapor deposition metal mask according to aspect 5 of the disclosure, the length, in the second direction, of each of the one or more openings arrayed in the second direction is preferably greater as the one or more openings arrayed in the second direction are farther from the center in the first direction, in aspect 4 described above.

With the above configuration, it is possible to provide a scan vapor deposition metal mask with which high-resolution, linear vapor deposition film patterns with a further even film thickness can be formed on a substrate.

In a scan vapor deposition metal mask according to aspect 6 of the disclosure, the plurality of openings are formed in an identical shape, and the number of the one or more openings arrayed in the second direction preferably increases as the one or more openings arrayed in the second direction are farther from the center in the first direction, in aspect 4 described above.

With the above configuration, it is possible to provide a scan vapor deposition metal mask including a plurality of openings in an identical shape with which high-resolution, linear vapor deposition film patterns with a further even film thickness can be formed on a substrate.

In a scan vapor deposition metal mask according to aspect 7 of the disclosure, it is preferable that, in each of the first unit opening groups, each two of the plurality of openings adjacent to each other in the second direction be arranged at a second interval from each other, the second interval being equal to or greater than the first interval, in any of aspects 1 to 6 described above.

With the above configuration, the second interval, i.e., the interval between adjacent openings in the second direction can also be increased to the first interval or greater, and hence higher opening positioning accuracy and higher opening pattern accuracy can be fulfilled.

A scan vapor deposition metal mask according to aspect 8 of the disclosure, the plurality of openings may belong to a single one of the second unit opening groups in any of aspects 1 to 7 described above.

With the above configuration, it is possible to provide a relatively small-sized scan vapor deposition metal mask with which a high-resolution, linear vapor deposition film pattern can be formed even on a large-sized substrate.

In a scan vapor deposition metal mask according to aspect 9 of the disclosure, it is preferable that the plurality of openings belong to two or more of the second unit opening groups, and the second unit opening groups be arranged by being alternately shifted from each other in the second direction, the second unit opening groups not being adjacent to each other in the first direction, in any of aspects 1 to 7 described above.

With the above configuration, it is possible to provide a scan vapor deposition metal mask with which a high-resolution, linear vapor deposition film pattern can be highly efficiently formed even on a large-sized substrate.

A vapor deposition device according to aspect 10 of the disclosure includes: the scan vapor deposition metal mask according to aspect 8 described above; a vapor deposition particle emission portion including an emission port configured to emit vapor particles; and a substrate with the vapor deposit particles emitted from the emission port of the vapor deposition particle emission portion and vapor-deposited on the substrate through the scan vapor deposition metal mask. It is preferable that the emission port be arranged at a position enabling the emission port to supply the vapor deposition particles to each of the openings in the second unit opening group, the emission port facing the scan vapor deposition metal mask, and the linear vapor deposition film pattern having an identical width in the first direction and aligned with the second direction be formed on the substrate while either one of the substrate and a vapor deposition unit including the scan vapor deposition metal mask and the vapor deposition particle emission portion be moved in the second direction with respect to another.

With the above configuration, it is possible to provide a vapor deposition device which includes a relatively small-sized scan vapor deposition metal mask and which is capable of forming a high-resolution, linear vapor deposition film pattern even on a large-sized substrate.

A vapor deposition device according to aspect 11 of the disclosure includes: the scan vapor deposition metal mask according to aspect 9; a vapor deposition particle emission portion including a plurality of emission ports configured to emit vapor deposition particles; a restriction plate unit included between the scan vapor deposition metal mask and the vapor deposition particle emission portion; and a substrate with the vapor deposit particles emitted from the plurality of emission ports of the vapor deposition particle emission portion and vapor-deposited on the substrate through the restriction plate unit and the scan vapor deposition metal mask. It is preferable that, in the restriction plate unit, through holes be arranged by being alternately shifted from each other in the second direction, each of the through holes being for restricting an incident angle of vapor deposition particles to the scan vapor deposition metal mask within a certain range, the vapor deposition particles being emitted from a corresponding one of the plurality of emission ports, the through holes facing the respective second unit opening groups of the scan vapor deposition metal mask, the vapor deposition particles emitted from each of the plurality of emission ports be supplied, through a corresponding one of the through holes arranged above, to a corresponding one of the openings in a corresponding one of the second unit opening groups, the corresponding opening being positioned immediately above the corresponding through hole, and the linear vapor deposition film pattern having an identical width in the first direction and aligned with the second direction be formed on the substrate while either one of the substrate and a vapor deposition unit including the scan vapor deposition metal mask, the restriction plate unit, and the vapor deposition particle emission portion is moved in the second direction with respect to another.

With the above method, it is possible to provide a vapor deposition device capable of highly efficiently forming a high-resolution, linear vapor deposition film pattern even on a large-sized substrate.

A vapor deposition device according to aspect 12 of the disclosure, the plurality of emission ports are preferably alternately shifted from each other in the second direction, each of the emission ports being positioned at a substantial center of the corresponding through hole, in aspect 11 described above.

With the above configuration, it is possible to provide a vapor deposition device capable of using an area with the highest density of vapor deposition particles and enabling high material use efficiency while being capable of reducing a tact time.

A vapor deposition method according to aspect 13 of the disclosure is a vapor deposition method for forming vapor deposition film patterns on a substrate by using a vapor deposition particle emission portion including an emission port configured to emit vapor deposition particles and a scan vapor deposition metal mask including a plurality of openings having an identical width in a first direction, a first unit opening group in the scan vapor deposition metal mask being constituted by part of the plurality of openings, each two of the part of the plurality of openings adjacent to each other in the first direction being arranged at a first interval from each other, one or more of the part of the plurality of openings being arrayed in a second direction orthogonal to the first direction, the plurality of openings belonging to one second unit opening group constituted by N (N is an integer of two or more) of the first unit opening groups, the N first unit opening groups being arranged by being shifted from each other in the second direction, the first unit opening groups not being adjacent to each other in the first direction, while each two of the first unit opening groups adjacent to each other in the second direction being arranged by being shifted from each other in the first direction by 1/N times the first interval, in each of the first unit opening groups, the one or more of the plurality of openings arrayed in the second direction serving as one or more of openings forming a linear vapor deposition film pattern having an identical width in the first direction and aligned with the second direction. The vapor deposition method includes: forming a first vapor deposition film pattern having a linear shape, aligned with the second direction, and having an identical width in the first direction, while moving either one of the substrate and a vapor deposition unit including the scan vapor deposition metal mask and the vapor deposition particle emission portion, with respect to another in the second direction; after forming the first vapor deposition film pattern, forming a second vapor deposition film pattern having a linear shape, aligned with the second direction, and having an identical width in the first direction, while moving the one of the substrate and the vapor deposition unit in the second direction, after moving the one in the first direction, with respect to the other; and after forming the second vapor deposition film pattern, forming a third vapor deposition film pattern having a linear shape, aligned with the second direction, and having an identical width in the first direction, while moving the one of the substrate and the vapor deposition unit in the second direction, after moving the one in the first direction, with respect to the other.

With the above method, it is possible to provide a vapor deposition method in which a high-resolution, linear vapor deposition film pattern can be formed even on a large-sized substrate, by using a relatively small-sized scan vapor deposition metal mask.

A vapor deposition method according to aspect 14 of the disclosure is a vapor deposition method for forming vapor deposition film patterns on a substrate by using a vapor deposition particle emission portion including a plurality of emission ports configured to emit vapor deposition particles, a scan vapor deposition metal mask including a plurality of openings having an identical width in a first direction, and a restriction plate unit included between the scan vapor deposition metal mask and the vapor deposition particle emission portion and including a plurality of through holes for restricting an incident angle of vapor deposition particles to the scan vapor deposition metal mask within a certain range, the vapor deposition particles being emitted from a corresponding one of the plurality of emission ports, a first unit opening group in the scan vapor deposition metal mask being constituted by part of the plurality of openings, each two of the part of the plurality of openings adjacent to each other in the first direction being arranged at a first interval from each other, one or more of the part of the plurality of openings being arrayed in a second direction orthogonal to the first direction, the plurality of openings belonging to two or more second unit opening groups each constituted by N (N is an integer of two or more) of the first unit opening groups, the N first unit opening groups being arranged by being shifted from each other in the second direction, the first unit opening groups not being adjacent to each other in the first direction, while each two of the first unit opening groups adjacent to each other in the second direction being arranged by being shifted from each other in the first direction by 1/N times the first interval, in each of the first unit opening groups, one or more openings of the plurality of openings arrayed in the second direction serving as openings for forming a linear vapor deposition film pattern having an identical width in the first direction and aligned with the second direction. The vapor deposition method includes: forming a first vapor deposition film pattern having a linear shape, aligned with the second direction, and having an identical width in the first direction, while moving either one of a vapor deposition unit including the restriction plate unit, the scan vapor deposition metal mask, and the vapor deposition particle emission portion, and the substrate, with respect to another in the second direction; after forming the first vapor deposition film pattern, forming a second vapor deposition film pattern having a linear shape, aligned with the second direction, and having an identical width in the first direction, while moving the one of the vapor deposition unit and the substrate, after moving the one in the first direction, with respect to the other in the second direction; and after forming the second vapor deposition film pattern, forming a third vapor deposition film pattern having a linear shape, aligned with the second direction, and having an identical width in the first direction, while moving the one of the vapor deposition unit and the substrate, after moving the one in the first direction, with respect to the other in the second direction.

With the above method, it is possible to provide a vapor deposition method in which a high-resolution, linear vapor deposition film pattern can be highly efficiently formed even on a large-sized substrate.

An electroluminescence display device according to aspect 15 of the disclosure includes the substrate including the first vapor deposition film pattern, the second vapor deposition film pattern, and the third vapor deposition film pattern formed thereon by the vapor deposition method according to aspect 13 or 14 described above.

With the above configuration, it is possible to provide a high-resolution, large-sized electroluminescence display device.

### Supplementary Matters

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### INDUSTRIAL APPLICABILITY

The disclosure can be used for a scan vapor deposition metal mask, a vapor deposition device, a vapor deposition method, and an electroluminescence display device.

### REFERENCE SIGNS LIST

1 Scan vapor deposition metal mask
2 Opening
2a First unit opening group
2a′ First unit opening group
2b Second unit opening group
3 Vapor deposition particle emission portion
3a Emission port
4 Vapor deposition unit
5 Substrate
6 Vapor deposition film pattern
7 Vapor deposition film pattern
8 Vapor deposition film pattern
10 Vapor deposition device
11 Scan vapor deposition metal mask
12 Opening
12a First unit opening group
12a′ First unit opening group
12a″ First unit opening group
12b Second unit opening group
15 Substrate
16 Vapor deposition film pattern
17 Vapor deposition film pattern
18 Vapor deposition film pattern
21 Scan vapor deposition metal mask
22 Opening
22a First unit opening group
22a′ First unit opening group
25 Substrate
26 Vapor deposition film pattern
27 Vapor deposition film pattern
28 Vapor deposition film pattern
31 Scan vapor deposition metal mask
32a First unit opening group
32a′ First unit opening group
32b Second unit opening group
32c Opening
32d Opening
32e Opening
32f Opening
41 Scan vapor deposition metal mask
42 Opening
42a First unit opening group
42a′ First unit opening group
42b Second unit opening group
50 Vapor deposition device
51 Scan vapor deposition metal mask
51a Scan vapor deposition metal mask
52 Opening
52a First unit opening group
52a′ First unit opening group
52b Second unit opening group
53 Restriction plate (restriction plate unit)
53a Through hole
53b Through hole
54 Vapor deposition particle emission portion
54a Emission port
55 Vapor deposition unit
56 Substrate
57 Vapor deposition film pattern
58 Vapor deposition film pattern
59 Vapor deposition film pattern
64 Vapor deposition particle emission portion
64a Emission port
64b Emission port
65 Vapor deposition device
66 Sealing resin
67 Sealing substrate
70 Organic EL display device (electroluminescence device)

1. A scan vapor deposition metal mask comprising a plurality of openings formed into an identical width in a first direction,
wherein each of first unit opening groups is constituted by part of the plurality of openings, each two of the part of the plurality of openings adjacent to each other in the first direction being arranged at a first interval from each other, one or more of the part of the plurality of openings being arrayed in a second direction orthogonal to the first direction,
the plurality of openings belong to one or more second unit opening groups each constituted by N (N is an integer of two or more) of the first unit opening groups,
the N first unit opening groups are arranged by being shifted from each other in the second direction, the first unit opening groups not being adjacent to each other in the first direction, while each two of the first unit opening groups adjacent to each other in the second direction are arranged by being shifted from each other in the first direction by 1/N times the first interval, and
in each of the first unit opening groups, one or more openings of the plurality openings arrayed in the second direction serve as openings for forming a linear vapor deposition film pattern having an identical width in the first direction and aligned with the second direction.

2. The scan vapor deposition metal mask according to claim 1,
wherein the N includes 2.

3. The scan vapor deposition metal mask according to claim 1,
wherein the N includes 3.

4. The scan vapor deposition metal mask according to claim 1,
wherein a total length, in the second direction, of the one or more openings arrayed in the second direction is greater as the one or more openings arrayed in the second direction are farther from a center in the first direction.

5. The scan vapor deposition metal mask according to claim 4,
wherein a length, in the second direction, of each of the one or more openings arrayed in the second direction is greater as the one or more openings arrayed in the second direction are farther from the center in the first direction.

6. The scan vapor deposition metal mask according to claim 4,
wherein the plurality of openings are formed into an identical shape, and
the number of the one or more openings arrayed in the second direction increases as the one or more openings arrayed in the second direction are farther from the center in the first direction.

7. The scan vapor deposition metal mask according to claim 1,
wherein in each of the first unit opening groups, each two of the plurality of openings adjacent to each other in the second direction are arranged at a second interval from each other, the second interval being equal to or greater than the first interval.

8. The scan vapor deposition metal mask according to claim 1,
wherein the plurality of openings belong to a single one of the second unit opening groups.

9. The scan vapor deposition metal mask according to claim 1,
wherein the plurality of openings belong to two or more of the second unit opening groups, and
the second unit opening groups are arranged by being alternately shifted from each other in the second direction, the second unit opening groups not being adjacent to each other in the first direction.

10. A vapor deposition device comprising:
the scan vapor deposition metal mask according to claim 8;
a vapor deposition particle emission portion including an emission port configured to emit vapor particles; and
a substrate with the vapor deposit particles emitted from the emission port of the vapor deposition particle emission portion and vapor-deposited on the substrate through the scan vapor deposition metal mask,
wherein the emission port is arranged at a position enabling the emission port to supply the vapor deposition particles to each of the openings in the second unit opening group, the emission port facing the scan vapor deposition metal mask, and
the linear vapor deposition film pattern having an identical width in the first direction and aligned with the second direction is formed on the substrate while either one of the substrate and a vapor deposition unit including the scan vapor deposition metal mask and the vapor deposition particle emission portion is moved in the second direction with respect to another.

11. A vapor deposition device comprising:
the scan vapor deposition metal mask according to claim 9;
a vapor deposition particle emission portion including a plurality of emission ports configured to emit vapor deposition particles;
a restriction plate unit included between the scan vapor deposition metal mask and the vapor deposition particle emission portion; and
a substrate with the vapor deposit particles emitted from the plurality of emission ports of the vapor deposition particle emission portion and vapor-deposited on the substrate through the restriction plate unit and the scan vapor deposition metal mask,
wherein, in the restriction plate unit, through holes are arranged by being alternately shifted from each other in the second direction, each of the through holes being for restricting an incident angle of vapor deposition particles to the scan vapor deposition metal mask within a certain range, the vapor deposition particles being emitted from a corresponding one of the plurality of emission ports, the through holes facing the respective second unit opening groups of the scan vapor deposition metal mask,
the vapor deposition particles emitted from each of the plurality of emission ports are supplied, through a corresponding one of the through holes arranged above, to a corresponding one of the openings in a corresponding one of the second unit opening groups, the corresponding opening being positioned immediately above the corresponding through hole, and
the linear vapor deposition film pattern having an identical width in the first direction and aligned with the second direction is formed on the substrate while either one of the substrate and a vapor deposition unit including the scan vapor deposition metal mask, the restriction plate unit, and the vapor deposition particle emission portion is moved in the second direction with respect to another.

12. The vapor deposition device according to claim 11,
wherein the plurality of emission ports are arranged by being alternately shifted from each other in the second direction, each of the emission ports being positioned at a substantial center of the corresponding through hole.

13. A vapor deposition method for forming vapor deposition film patterns on a substrate by using a vapor deposition particle emission portion including an emission port configured to emit vapor deposition particles and a scan vapor deposition metal mask including a plurality of openings having an identical width in a first direction,
a first unit opening group in the scan vapor deposition metal mask being constituted by part of the plurality of openings, each two of the part of the plurality of openings adjacent to each other in the first direction being arranged at a first interval from each other, one or more of the part of the plurality of openings being arrayed in a second direction orthogonal to the first direction,
the plurality of openings belonging to one second unit opening group constituted by N (N is an integer of two or more) of the first unit opening groups,
the N first unit opening groups being arranged by being shifted from each other in the second direction, the first unit opening groups not being adjacent to each other in the first direction, while each two of the first unit opening groups adjacent to each other in the second direction being arranged by being shifted from each other in the first direction by 1/N times the first interval, and
in each of the first unit opening groups, one or more openings of the plurality of openings arrayed in the second direction serving as openings for forming a linear vapor deposition film pattern having an identical width in the first direction and aligned with the second direction, the vapor deposition method comprising:
forming a first vapor deposition film pattern having a linear shape, aligned with the second direction, and having an identical width in the first direction, while moving either one of the substrate and a vapor deposition unit including the scan vapor deposition metal mask and the vapor deposition particle emission portion, with respect to another in the second direction;
after forming the first vapor deposition film pattern, forming a second vapor deposition film pattern having a linear shape, aligned with the second direction, and having an identical width in the first direction, while moving the one of the substrate and the vapor deposition unit in the second direction, after moving the one in the first direction, with respect to the other; and
after forming the second vapor deposition film pattern, forming a third vapor deposition film pattern having a linear shape, aligned with the second direction, and having an identical width in the first direction, while moving the one of the substrate and the vapor deposition unit in the second direction, after moving the one in the first direction, with respect to the other.

14. A vapor deposition method for forming vapor deposition film patterns on a substrate by using a vapor deposition particle emission portion including a plurality of emission ports configured to emit vapor deposition particles, a scan vapor deposition metal mask including a plurality of openings having an identical width in a first direction, and a restriction plate unit included between the scan vapor deposition metal mask and the vapor deposition particle emission portion and including a plurality of through holes for restricting an incident angle of vapor deposition particles to the scan vapor deposition metal mask within a certain range, the vapor deposition particles being emitted from a corresponding one of the plurality of emission ports,
a first unit opening group in the scan vapor deposition metal mask being constituted by part of the plurality of openings, each two of the part of the plurality of openings adjacent to each other in the first direction being arranged at a first interval from each other, one or more of the part of the plurality of openings being arrayed in a second direction orthogonal to the first direction,
the plurality of openings belonging to two or more second unit opening groups each constituted by N (N is an integer of two or more) of the first unit opening groups,
the N first unit opening groups being arranged by being shifted from each other in the second direction, the first unit opening groups not being adjacent to each other in the first direction, while each two of the first unit opening groups adjacent to each other in the second direction being arranged by being shifted from each other in the first direction by 1/N times the first interval, and
in each of the first unit opening groups, one or more openings of the plurality of openings arrayed in the second direction serving as openings for forming a linear vapor deposition film pattern having an identical width in the first direction and aligned with the second direction, the vapor deposition method comprising:
forming a first vapor deposition film pattern having a linear shape, aligned with the second direction, and having an identical width in the first direction, while moving either one of a vapor deposition unit including the restriction plate unit, the scan vapor deposition metal mask, and the vapor deposition particle emission portion, and the substrate, with respect to another in the second direction;
after forming the first vapor deposition film pattern, forming a second vapor deposition film pattern having a linear shape, aligned with the second direction, and having an identical width in the first direction, while moving the one of the vapor deposition unit and the substrate, after moving the one in the first direction, with respect to the other in the second direction; and
after forming the second vapor deposition film pattern, forming a third vapor deposition film pattern having a linear shape, aligned with the second direction, and having an identical width in the first direction, while moving the one of the vapor deposition unit and the substrate, after moving the one in the first direction, with respect to the other in the second direction.

15. An electroluminescence display device comprising the substrate including the first vapor deposition film pattern, the second vapor deposition film pattern, and the third vapor deposition film pattern formed thereon by the vapor deposition method according to claim 13.
